(19) United States
(12) Patent Application Publication
(10) Pub. No.: US 2025/0054133 A1
(43) Pub. Date: Feb. 13, 2025

(54) SUBSTRATE PROCESSING APPARATUS AND MONITORING METHOD

(71) Applicant: SCREEN Holdings Co., Ltd., Kyoto (JP)

(72) Inventor: Shinji SHIMIZU, Kyoto-shi, Kyoto (JP)

(21) Appl. No.: 18/720,523

(22) PCT Filed: Jan. 25, 2023
(86) PCT No.: PCT/JP2023/002186

§ 371 Date: Jun. 14, 2024

(30) Foreign Application Priority Data
Mar. 18, 2022 (JP) 2022-043754

(51) Int. Cl. G06T 7/00; H04N 7/18

(52) U.S. Cl. CPC G06T 7/001; H04N 7/18; G06T 2207/20081; G06T 2207/30148

(57) ABSTRACT

A substrate processing apparatus includes a chamber, a substrate holder, a camera, and a controller. The substrate holder holds a substrate in the chamber. The camera captures an image of an imaging region including the monitoring target in the chamber, and generates captured image data. The controller specifies an environmental state in an imaging region, monitors the state of the monitoring target based on the captured image data in a first determination procedure corresponding to a first environmental state when the environmental state is in the first environmental state, and monitors the state of the monitoring target based on the captured image data in a second determination procedure corresponding to a second environmental state and different from the first determination procedure when the environmental state is the second environmental state different from the first environmental state.

### TECHNICAL FIELD

The present disclosure relates to a substrate processing apparatus and a monitoring method.

### BACKGROUND ART

Conventionally, in a process of manufacturing a semiconductor device or the like, various processing liquids such as pure water, a photoresist liquid, and an etching liquid are supplied to a substrate to perform various pieces of substrate processing such as cleaning processing and resist coating processing. A substrate processing apparatus in which discharges the processing liquid from a nozzle to a surface of the substrate while a substrate holder rotates the substrate in a horizontal posture is widely used as an apparatus performing substrate processing using these processing liquids. For example, the nozzle discharges the processing liquid at a processing position opposite to a center portion of an upper surface of the substrate in a vertical direction. The processing liquid attached to a center portion of the substrate receives centrifugal force accompanying the rotation of the substrate to spread on the surface of the substrate. The processing liquid acts on the surface of the substrate to perform processing on the substrate.

Whether the position of the nozzle is appropriate is monitored in such the substrate processing apparatus. For example, in Patent Document 1, image capturing means such as a camera is provided to monitor the position of the nozzle.

In Patent Document 1, the camera is provided above the substrate holder. The camera captures an image of an imaging region including the substrate and the nozzle held by the substrate holder, and generates a captured image. In Patent Document 1, a reference image including a nozzle is previously set, and the position of the nozzle is detected by matching processing between the captured image captured by the camera and the reference image.

### PRIOR ART DOCUMENT

### Patent Document

Patent Document 1: Japanese Patent Application Laid-Open No. 2015-173148

### SUMMARY

### Problem to be Solved by the Invention

In Patent Document 1, the position of the nozzle is monitored in substrate processing for the substrate. In this substrate processing, the substrate holder naturally holds the substrate. The captured image captured at this time includes the nozzle and the substrate. Specifically, the captured image includes the nozzle, and the substrate is included in a background region around the nozzle.

However, sometimes the processing liquid is discharged from the nozzle while the substrate holder does not hold the substrate. For example, in order to clean various components in the substrate processing apparatus, sometimes the processing liquid for cleaning is discharged from the nozzle while the substrate holder does not hold the substrate. Also in this cleaning processing, the position of the nozzle may be monitored. However, because the substrate holder does not hold the substrate, the captured image includes the nozzle but does not include the substrate. In this case, for example, the background region around the nozzle in the captured image includes the substrate holder.

The reference image used in the matching processing includes the nozzle that is a monitoring target. In a case where the substrate is included in the background region around the nozzle in the reference image, accuracy of the matching processing between the captured image that is captured while the substrate holder holds the substrate and the reference image is high. However, the accuracy of the matching processing between the captured image that is captured while the substrate holder does not hold the substrate and the reference image decreases. This is because the background region is different between the captured image and the reference image.

Similarly, in the case where the substrate is not included in the background region of the reference image, the accuracy of the matching processing between the captured image that is captured while the substrate holder holds the substrate and the reference image decreases.

As described above, when the position of the nozzle is detected in the same procedure in the state where the substrate holder holds the substrate and the state where the substrate holder does not hold the substrate, sometimes the detection accuracy decreases.

More generally, the monitoring accuracy decreases depending on an environmental state (in this case, whether the substrate holder holds the substrate) in the imaging region including the monitoring target (for example, the nozzle).

An object of the present disclosure is to provide a technique capable of monitoring the state of the monitoring target with high accuracy.

### Means to Solve the Problem

A first aspect is a substrate processing apparatus including: a chamber; a substrate holder that holds a substrate in the chamber; a camera that captures an image of an imaging region including a monitoring target in the chamber to generate captured image data; and a controller that specifies an environmental state in the imaging region, monitors a state of the monitoring target based on the captured image data in a first determination procedure corresponding to a first environmental state when the environmental state is in the first environmental state, and monitors the state of the monitoring target based on the captured image data in a second determination procedure corresponding to a second environmental state and different from the first determination procedure when the environmental state is in the second environmental state different from the first environmental state.

A second aspect is the substrate processing apparatus according to the first aspect, in which the controller specifies the environmental state based on the captured image data.

A third aspect is the substrate processing apparatus according to the first or second aspect, further including a storage in which a plurality of reference image data corresponding to the environmental state are recorded, in which the controller monitors the state of the monitoring target based on comparison between the captured image data and first reference image data corresponding to the first environmental state as the first determination procedure when the environmental state is in the first environmental state, and monitors the state of the monitoring target based on comparison between the captured image data and second reference image data corresponding to the second environmental state as the second determination procedure when the environmental state is in the second environmental state.

A fourth aspect is the substrate processing apparatus according to the third aspect, in which the first environmental state includes a state in which a predetermined object exists in the imaging region, the second environmental state includes a state in which the object does not exist in the imaging region, the first reference image data is an image including the object and the monitoring target, and the second reference image data is an image not including the object but including the monitoring target.

A fifth aspect is the substrate processing apparatus according to any one of the first to fourth aspects, in which an algorithm of the first determination procedure and an algorithm of the second determination procedure are different from each other.

A sixth aspect is the substrate processing apparatus according to any one of the first to fifth aspects, in which a threshold for monitoring the state of the monitoring target that is used in the first determination procedure is different from a threshold for monitoring the state of the monitoring target that is used in the second determination procedure.

A seventh aspect is the substrate processing apparatus according to the sixth aspect, further including a storage in which reference image data is recorded, in which the first environmental state includes a state in which a predetermined object exists in the imaging region, the second environmental state includes a state in which the object does not exist in the imaging region, the reference image data does not include the object and is an image including the monitoring target, and when the environmental state is the first environmental state, the controller monitors the state of the monitoring target by comparing a similarity ratio between the captured image data and the reference image data with a first threshold as the first determination procedure, and when the environmental state is the second environmental state, the controller sets the similarity ratio between the captured image data and the reference image data as the second determination procedure, the state of the monitoring target is monitored by comparison with a second threshold smaller than the first threshold.

An eighth aspect of the substrate processing apparatus according to the fourth or seventh aspect, further including a nozzle that supplies a processing liquid to the substrate from a nozzle processing position above the substrate held by the substrate holder, in which the object includes fumes that are generated above the substrate and derived from the processing liquid.

A ninth aspect is the substrate processing apparatus according to any one of the first to eighth aspects, in which the first environmental state includes a state in which a predetermined object exists in the imaging region, the second environmental state includes a state in which the object does not exist in the imaging region, the controller inputs the captured image data to a first learned model as the first determination procedure, and inputs the captured image data to a second learned model as the second determination procedure, the first learned model is a learned model generated based on a plurality of learning data including the monitoring target and the object, and classifies the captured image data into one of a normal category indicating that the captured image data is normal and an abnormal category indicating that the captured image data is abnormal, and the second learned model is a learned model generated based on a plurality of learning data not including the object but including the monitoring target, and classifies the captured image data into one of the normal category and the abnormal category.

A tenth aspect is the substrate processing apparatus according to any one of the first to ninth aspects, in which the monitoring target includes at least one of a chuck pin of the substrate holder, a nozzle that supplies a processing liquid to the substrate held by the substrate holder, and a cylindrical guard that receives the processing liquid scattered from a peripheral edge of the substrate held by the substrate holder.

An eleventh aspect of the substrate processing apparatus according to the fifth aspect, further including a nozzle that supplies a processing liquid to the substrate from a nozzle processing position above the substrate held by the substrate holder, in which the first environmental state includes a patterned substrate state in which a pattern is formed on an upper surface of the substrate held by the substrate holder, the second environmental state includes a uniform substrate state in which a pattern is not formed on the upper surface of the substrate held by the substrate holder, and the controller calculates an index indicating a variation in a pixel value in a discharge determination region located immediately below the nozzle in the captured image data and determines existence or non-existence of a droplet of the processing liquid dropped from the nozzle based on comparison between the index and a threshold as the first determination procedure when the environmental state is in the uniform substrate state, and inputs the captured image data to a learned model to determine the existence or non-existence of the droplet as the second determination procedure when the environmental state is in the patterned substrate state.

A twelfth aspect is the substrate processing apparatus according to the fifth aspect, further including a nozzle that supplies a processing liquid to the substrate held by the substrate holder, in which the first environmental state includes a fume existence state in which fumes derived from the processing liquid are generated above the substrate held by the substrate holder, the second environmental state includes a fume non-existence state in which the fumes are not generated, and the controller generates enhanced image data by performing contrast enhancement processing on the captured image data as the first determination procedure and monitors the state of the monitoring target based on the enhanced image data when the environmental state is in the fume existence state, and monitoring the state of the monitoring target based on the captured image data without performing the contrast enhancement processing as the second determination procedure when the environmental state is in the fume non-existence state.

A thirteenth aspect is a monitoring method including: an environmental state specifying step of specifying an environmental state in an imaging region including a monitoring target in a chamber accommodating a substrate holder holding a substrate; an imaging step of capturing an image of the imaging region by a camera to generate captured image data; and a monitoring step of monitoring a state of the monitoring target based on the captured image data in a first determination procedure corresponding to the first environmental state when the environmental state is in the first environmental state, and monitoring the state of the monitoring target based on the captured image data in a second determination procedure corresponding to the second environmental state and different from the first determination procedure when the environmental state is in a second environmental state different from the first environmental state.

### Effects of the Invention

According to the first and thirteenth aspects, the state of the monitoring target is monitored by the determination procedure according to the surrounding environmental state, so that the state of the monitoring target can be monitored with high accuracy.

According to the second aspect, the environmental state is specified based on the captured image data, so that the environmental state can be specified with high accuracy.

According to the third aspect, the state of the monitoring target is monitored based on the reference image data according to the environmental state and the captured image data, so that the state of the monitoring target can be monitored with high accuracy.

According to the fourth aspect, when the object exists in the imaging region, the captured image data includes the object. At this point, the controller compares the captured image data with the first reference image data including the object. In this comparison result, influence of the object is canceled, so that the controller can monitor the state of the monitoring target with higher accuracy by comparing the monitoring target in the captured image data with the state of the monitoring target in the first reference image data.

On the other hand, when the object does not exist in the imaging region, the captured image data does not include the object. At this point, the controller compares the captured image data with the second reference image data that does not include the object. This comparison result does not include the influence of the object, so that the controller can monitor the state of the monitoring target with higher accuracy by comparing the monitoring target in the captured image data with the monitoring target in the second reference image data.

According to the fifth aspect, the algorithm corresponding to the environmental state is used, so that the controller can monitor the state of the monitoring target with high accuracy.

According to the seventh aspect, in the state where the object exists, the first threshold compared with the similarity ratio is large. For this reason, the state of the monitoring target can be monitored with higher accuracy. On the other hand, in the state where the object does not exist, the second threshold compared with the similarity ratio is small. For this reason, erroneous detection of an abnormality due to a decrease in similarity ratio caused by the existence or non-existence of the object between the captured image and the reference image can be reduced.

According to the eighth aspect, the state of the monitoring target can be appropriately monitored according to the existence or non-existence of fumes.

According to the ninth aspect, the learned model according to the environmental state is used, so that the state of the monitoring target can be monitored with higher accuracy.

According to the tenth aspect, the state of at least one of the chuck pin, the nozzle, and the guard can be appropriately monitored.

According to the eleventh aspect, when the pattern is formed on the substrate, the existence or non-existence of the droplet (dripping) is determined based on the comparison between the index indicating the variation in the discharge determination region and the threshold. Accordingly, the controller can determine the existence or non-existence of the droplets with a light processing load and high accuracy.

On the other hand, when the pattern is formed on the substrate, the index of the discharge determination region becomes high even when droplet is not generated.

In the eleventh aspect, when the pattern is formed on the substrate, the existence or non-existence of the droplet is determined using the learned model. Accordingly, the controller can determine the existence or non-existence of the droplets with high accuracy even when the pattern is formed on the substrate.

According to the twelfth aspect, when the fumes are generated, the state of the monitoring target is monitored using the enhanced image data. For this reason, the influence of the decrease in the contrast caused by the fumes can be reduced, and the state of the monitoring target can be monitored with higher accuracy.

On the other hand, when the fumes are not generated, the contrast enhancement processing is not performed. Accordingly, the controller can monitor the state of the monitoring target with a light processing load.

### BRIEF DESCRIPTION OF DRAWINGS

FIG. 1 is a plan view schematically illustrating an example of a configuration of a substrate processing apparatus.

FIG. 2 is a plan view schematically illustrating an example of a configuration of a processing unit according to the first embodiment.

FIG. 3 is a longitudinal sectional view schematically illustrating the example of the configuration of the processing unit according to the first embodiment.

FIG. 4 is a functional block diagram schematically illustrating an example of an internal configuration of a controller.

FIG. 5 is a flowchart illustrating an example of a flow of substrate processing.

FIG. 6 is a view schematically illustrating an example of a captured image captured by a camera.

FIG. 7 is a view schematically illustrating an example of the captured image captured by the camera.

FIG. 8 is a flowchart illustrating an example of a flowchart of monitoring processing by a processing unit.

FIG. 9 is a flowchart illustrating a specific example of a monitoring process.

FIG. 10 is a view schematically illustrating an example of the captured image when a droplet of a processing liquid falls from a discharge port of a first nozzle.

FIG. 11 is a view schematically illustrating an example of the captured image when the droplet of the processing liquid falls from the discharge port of the first nozzle.

FIG. 12 is a flowchart illustrating a specific example of the monitoring process.

FIG. 13 is a view schematically illustrating an example of the captured image captured by the camera.

FIG. 14 is a view schematically illustrating an example of the captured image when the processing liquid scatters from a peripheral edge of a substrate.

FIG. 15 is a flowchart illustrating a specific example of the monitoring process.

FIG. 16 is a view schematically illustrating an example of the captured image when fumes are generated.

FIG. 17 is a flowchart illustrating a specific example of the monitoring process.

FIG. 18 is a view schematically illustrating an example of a configuration of a batch-type processing unit according to a second embodiment.

FIG. 19 is a flowchart illustrating a specific example of a monitoring process according to the second embodiment.

FIG. 20 is a flowchart illustrating a specific example of a monitoring process according to a third embodiment.

### DESCRIPTION OF EMBODIMENTS

Hereinafter, embodiments will be described with reference to the accompanying drawings. The drawings are schematically illustrated, and omission or simplification of a configuration is appropriately made for convenience. A mutual relationship between a size and a position of the configuration illustrated in the drawings is not necessarily described accurately, but can appropriately be changed.

In the following description, the same components are denoted by the same reference numeral, and it is assumed that names and functions of the same components are also similar. Accordingly, the detailed description of the same component is occasionally omitted in order to avoid duplication.

In the following description, even when ordinal numbers such as “first” or “second” are used, these terms are used only for convenience to facilitate understanding of contents of the embodiments, and are not limited to the order that can be generated by these ordinal numbers.

In the case where expressions indicating a relative or absolute positional relationship (for example, “in one direction”, “along one direction”, “parallel”, “orthogonal”, “center”, “concentric”, and “coaxial”) are used, the expressions shall not only strictly represent a positional relationship, but also represent a state of being displaced relative to an angle or a distance to an extent that a tolerance or a comparable function is obtained, unless otherwise specified. When expressions indicating an equal state (for example, “same”, “equal”, and “homogeneous”) are used, unless otherwise specified, the expressions shall not only represent a quantitatively strictly equal state, but also represent a state in which there is a difference in obtaining a tolerance or a similar function. In the case where expressions indicating a shape (for example, “quadrangular” or “cylindrical”) are used, unless otherwise specified, the expressions shall not only represent the shape geometrically and strictly, but also represent a shape having, for example, unevenness or chamfering within a range in which the same level of effect can be obtained. When expressions “comprising”, “owning”, “possessing”, “including” or “having” one component are used, the expressions are not an exclusive expression excluding presence of other components. When the expression “at least any one of A, B, and C” is used, the expression includes only A, only B, only C, any two of A, B and C, and all of A, B and C.

### First Embodiment

### <Overall Configuration of Substrate Processing Apparatus>

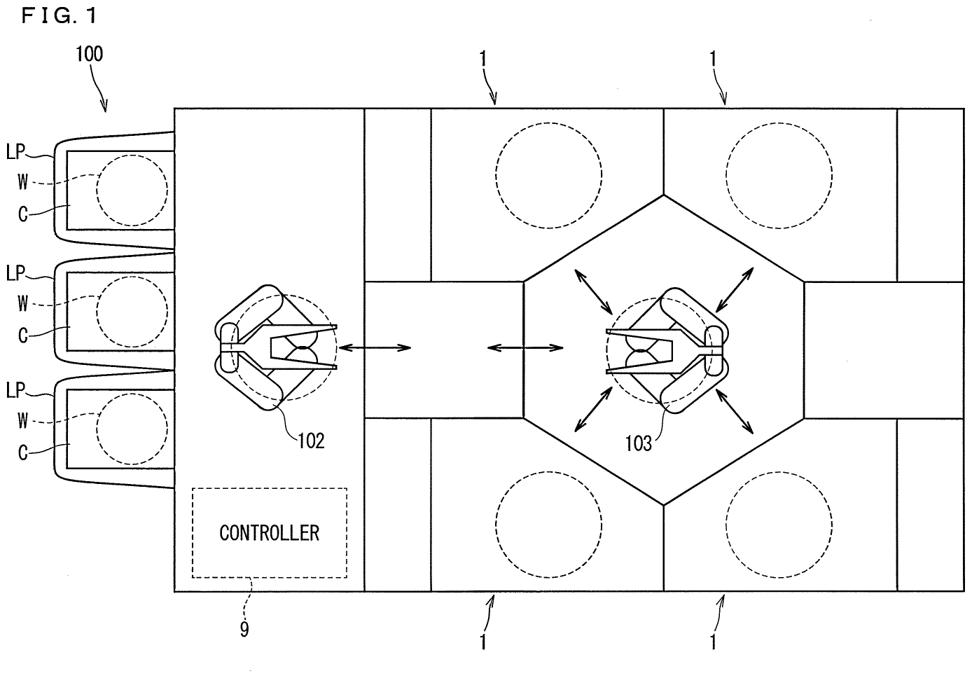

FIG. 1 is a plan view schematically illustrating an example of a configuration of a substrate processing apparatus 100. The substrate processing apparatus 100 is a single wafer type processing apparatus that processes a substrates W to be processed one by one. The substrate processing apparatus 100 performs liquid processing on the substrate W using a chemical liquid and a rinse liquid such as pure water, and then performs drying processing. For example, the substrate W is a semiconductor substrate and has a disk shape. For example, a mixed solution (SC1) of ammonia and a hydrogen peroxide solution, a mixed aqueous solution (SC2) of hydrochloric acid and a hydrogen peroxide solution, or a DHF solution (dilute hydrofluoric acid) is used as the chemical liquid. In the following description, the chemical liquid, the rinse liquid, an organic solvent, and the like are collectively referred to as a “processing liquid”. Not only cleaning processing but also a chemical liquid removing an unnecessary film, the chemical liquid for etching, or the like are included in the “processing liquid”.

The substrate processing apparatus 100 includes a plurality of processing units 1, a load port LP, an indexer robot 102, a main conveyance robot 103, and a controller 9.

The load port LP is an interface part that carries in and out the substrate W between the substrate processing apparatus 100 and the outside. A container (also referred to as a carrier) that accommodates a plurality of unprocessed substrates W is carried into the load port LP from the outside. The load port LP can hold a plurality of carriers. As described later, each substrate W is taken out from the carrier by the substrate processing apparatus 100, processed, and accommodated in the carrier again. The carrier that accommodates the plurality of processed substrates W is carried out from the load port LP to the outside.

The indexer robot 102 conveys the substrate W between each carrier held in the load port LP and the main conveyance robot 103. The main conveyance robot 103 conveys the substrate W between each processing unit 1 and the indexer robot 102.

The processing unit 1 performs the liquid processing and the drying processing on one substrate W. In the substrate processing apparatus 100 of the present embodiment, twelve processing units 1 having the same configuration are disposed. Specifically, four towers each including three processing units 1 stacked in a vertical direction are disposed so as to surround a periphery of the main conveyance robot 103. In FIG. 1, one of the processing units 1 that are stacked in three stages is schematically illustrated. The number of processing units 1 in the substrate processing apparatus 100 is not limited to twelve, but may be appropriately changed.

The main conveyance robot 103 is installed at a center of the four towers in which the processing units 1 are stacked. The main conveyance robot 103 carries the substrate W to be processed received from the indexer robot 102 into each processing unit 1. In addition, the main conveyance robot 103 carries out the processed substrate W from each processing unit 1 and transfers the substrate W to the indexer robot 102. The controller 9 controls operation of each component of the substrate processing apparatus 100.

One of the 12 processing units 1 loaded on the substrate processing apparatus 100 will be described below.

### <Processing Unit>

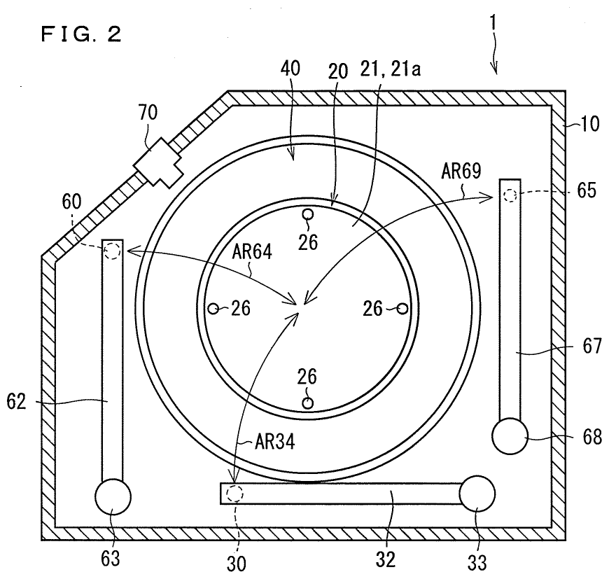

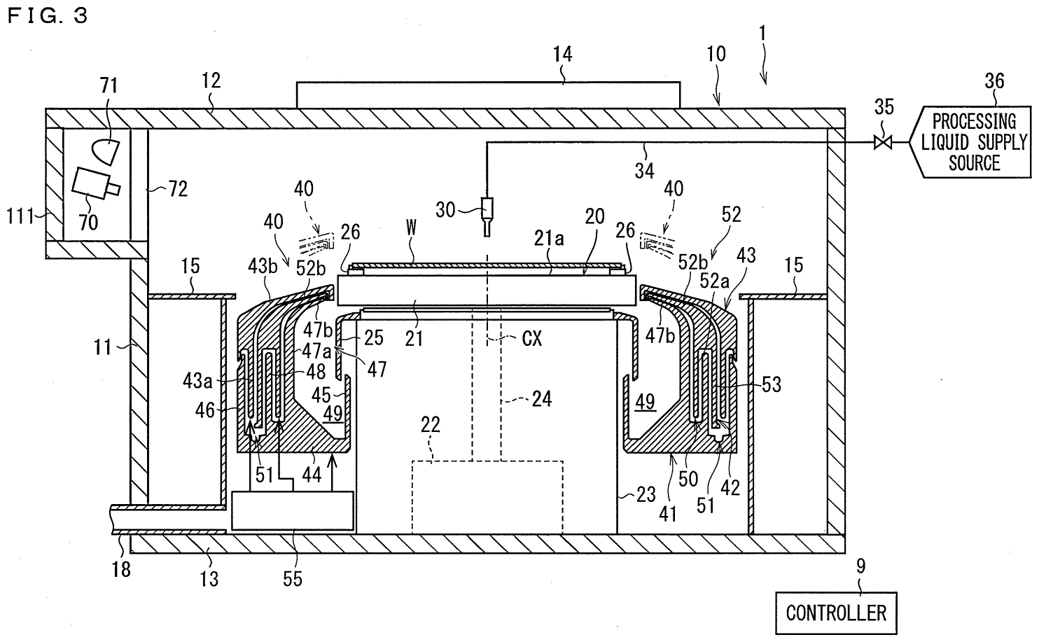

FIG. 2 is a plan view schematically illustrating an example of a configuration of the processing unit 1 according to the first embodiment. FIG. 3 is a longitudinal sectional view schematically illustrating the example of the configuration of the processing unit 1 according to the first embodiment.

In the examples of FIGS. 2 and 3, the processing unit 1 includes a substrate holder 20, a first nozzle 30, a second nozzle 60, a third nozzle 65, a guard part 40, and a camera 70.

In the examples of FIGS. 2 and 3, the processing unit 1 also includes a chamber 10. The chamber 10 includes a side wall 11 along the vertical direction, a ceiling wall 12 that closes an upper side of a space surrounded by the side wall 11, and a floor wall 13 that closes a lower side. A processing space is formed in a space surrounded by the side wall 11, the ceiling wall 12, and the floor wall 13. On a part of the side wall 11 of the chamber 10, a carry-in and -out port for the main conveyance robot 103 to carry-in and -out the substrate W and a shutter that opens and closes the carry-in and -out port are provided (both are not illustrated). The chamber 10 accommodates the substrate holder 20, the first nozzle 30, the second nozzle 60, the third nozzle 65, and the guard part 40.

In the example of FIG. 3, a fan filter unit (FFU) 14, which further cleans the air in the clean room where the substrate processing apparatus 100 is installed and supplies the air to the processing space in the chamber 10, is attached to the ceiling wall 12 of the chamber 10. The fan filter unit 14 includes a fan and a filter (for example, a high efficiency particulate air (HEPA) filter) that take in the air in the clean room to send the air into the chamber 10, and forms a down flow of clean air in the processing space in the chamber 10. In order to uniformly disperse the clean air supplied from the fan filter unit 14, a punching plate having a large number of blow-out holes may be provided immediately below the ceiling wall 12.

The substrate holder 20 holds the substrate W in a horizontal posture (posture in which the normal line is along the vertical direction) and rotates the substrate W around a rotation axis CX (see FIG. 3). The rotation axis CX is an axis along the vertical direction and passing through the center portion of the substrate W. The substrate holder 20 is also referred to as a spin chuck. FIG. 2 illustrates the substrate holder 20 in the state where the substrate is not held.

In the examples of FIGS. 2 and 3, the substrate holder 20 includes a disk-shaped spin base 21 provided in a horizontal posture. An outer diameter of the disk-shaped spin base 21 is slightly larger than a diameter of the circular substrate W held by the substrate holder 20 (see FIG. 3). Accordingly, the spin base 21 includes an upper surface 21a opposite to the entire lower surface of the substrate W to be held in the vertical direction.

In the examples of FIGS. 2 and 3, a plurality of (four in the present embodiment) chuck pins 26 are erected on a peripheral edge portion of the upper surface 21a of the spin base 21. The plurality of chuck pins 26 is arranged at equal intervals along a circumference corresponding to the peripheral edge of the circular substrate W. Each of the chuck pins 26 is provided so as to be drivable between a holding position in contact with the peripheral edge of the substrate W and an open position away from the peripheral edge of the substrate W. The plurality of chuck pins 26 are driven in conjunction with each other by a link mechanism (not illustrated) accommodated in the spin base 21. The substrate holder 20 can hold the substrate W in a horizontal posture close to the upper surface 21a above the spin base 21 by stopping the plurality of chuck pins 26 at the respective holding positions (see FIG. 3), and can release the holding of the substrate W by stopping the plurality of chuck pins 26 at the respective opening positions.

In the example of FIG. 3, an upper end of a rotation shaft 24 extending along the rotation axis CX is connected to the lower surface of the spin base 21. A spin motor 22 that rotates the rotation shaft 24 is provided below the spin base 21. The spin motor 22 rotates the spin base 21 in a horizontal plane by rotating the rotation shaft 24 around the rotation axis CX. Consequently, the substrate W held by the chuck pin 26 also rotates around the rotation axis CX.

In the example of FIG. 3, a tubular cover member 23 is provided so as to surround the spin motor 22 and the rotation shaft 24. The lower end of the cover member 23 is fixed to the floor wall 13 of the chamber 10, and the upper end reaches immediately below the spin base 21. In the example of FIG. 3, a flange-shaped member 25, which protrudes substantially horizontally outward from the cover member 23 and further bends and extends downward, is provided in the upper end portion of the cover member 23.

The first nozzle 30 discharges the processing liquid toward the substrate W and supplies the processing liquid to the substrate W. In the example of FIG. 2, the first nozzle 30 is attached to a tip of a nozzle arm 32. The nozzle arm 32 extends horizontally, and a base end thereof is connected to a nozzle support column 33. The nozzle support column 33 extends along the vertical direction and is provided so as to be rotatable around an axis along the vertical direction by an arm driving motor (not illustrated). When the nozzle support column 33 rotates, the first nozzle 30 moves in an arc shape between a nozzle processing position and a nozzle standby position in a space vertically above the substrate holder 20 as indicated by an arrow AR34 in FIG. 2. The nozzle processing position is a position at which the first nozzle 30 discharges the processing liquid onto the substrate W, and for example, is a position opposite to a central portion of the substrate W in the vertical direction. The nozzle standby position is a position at which the first nozzle 30 does not discharge the processing liquid onto the substrate W, and for example, is a position radially outside the peripheral edge of the substrate W. At this point, the radial direction is the radial direction with respect to the rotation axis CX. FIG. 2 illustrates the first nozzle 30 located at the nozzle standby position, and FIG. 3 illustrates the first nozzle 30 located at the nozzle processing position.

As illustrated in FIG. 3, the first nozzle 30 is connected to a processing liquid supply source 36 through a supply pipe 34. The processing liquid supply source 36 includes a tank that stores the processing liquid. A valve 35 is provided in the supply pipe 34. When the valve 35 is opened, the processing liquid is supplied from the processing liquid supply source 36 to the first nozzle 30 through the supply pipe 34, and discharged from a discharge port formed on the lower end surface of the first nozzle 30. The first nozzle 30 may be configured to be supplied with a plurality of kinds of processing liquids (including at least pure water).

The second nozzle 60 is attached to a tip of a nozzle arm 62, and a base end of the nozzle arm 62 is connected to a nozzle support column 63. When the arm driving motor (not illustrated) rotates the nozzle support column 63, the second nozzle 60 moves in an arc shape in a space vertically above the substrate holder 20 as indicated by an arrow AR64. Similarly, a third nozzle 65 is attached to a tip of a nozzle arm 67, and the proximal end of the nozzle arm 67 is connected to a nozzle support column 68. When the arm driving motor (not illustrated) rotates the nozzle support column 68, the third nozzle 65 moves in an arc shape in the space vertically above the substrate holder 20 as indicated by an arrow AR69.

Similarly to the first nozzle 30, each of the second nozzle 60 and the third nozzle 65 is connected to a processing liquid supply source (not illustrated) through a supply pipe (not illustrated). A valve is provided in each supply pipe, and supply and stop of the processing liquid is switched by opening and closing the valve. The number of nozzles provided in the processing unit 1 is not limited to three, but may be at least one.

In the liquid processing, for example, the processing unit 1 causes the first nozzle 30 to discharge the processing liquid toward the upper surface of the substrate W while rotating the substrate W by the substrate holder 20. The processing liquid attached to the upper surface of the substrate W spreads on the upper surface of the substrate W by receiving centrifugal force accompanying the rotation, and scatters from the peripheral edge of the substrate W. By this liquid processing, processing according to the kind of the processing liquid can be performed on the upper surface of the substrate W.

The guard part 40 is a member that receives the processing liquid scattered from the peripheral edge of the substrate W. The guard part 40 has a tubular shape surrounding the substrate holder 20, and for example, includes a plurality of guards that can ascend and descend independently of each other. The guard may also be referred to as a processing cup. In the example of FIG. 3, an inner guard 41, a middle guard 42, and an outer guard 43 are illustrated as the plurality of guards. Each of the guards 41 to 43 surrounds the periphery of the substrate holder 20 and has a shape substantially rotationally symmetric with respect to the rotation axis CX.

In the example of FIG. 3, the inner guard 41 integrally includes a bottom part 44, an inner wall part 45, an outer wall part 46, a first guide part 47, and a middle wall part 48. The bottom part 44 has an annular shape in planar view. The inner wall part 45 and the outer wall part 46 have a cylindrical shape, and are erected on an inner peripheral edge and an outer peripheral edge of the bottom part 44, respectively. The first guide part 47 includes a tubular part 47a erected on the bottom part 44 between the inner wall part 45 and the outer wall part 46 and an inclined part 47b that approaches the rotation axis CX as it goes vertically upward from the upper end of the tubular part 47a. The middle wall part 48 has a cylindrical shape, and is erected on the bottom part 44 between the first guide part 47 and the outer wall part 46.

In the state where the guards 41 to 43 are raised (see an imaginary line in FIG. 3), the processing liquid scattered from the peripheral edge of the substrate W is received by the inner peripheral surface of the first guide part 47, flows down along the inner peripheral surface, and is received by a disposal groove 49. The disposal groove 49 is an annular groove formed by the inner wall part 45, the first guide part 47, and the bottom part 44. An exhaust liquid mechanism (not illustrated), which discharges the processing liquid and forcibly exhausts the inside of the disposal groove 49, is connected to the disposal groove 49.

The middle guard 42 integrally includes a second guide part 52 and a cylindrical processing liquid separation wall 53 connected to the second guide part 52. The second guide part 52 includes a tubular part 52a having a cylindrical shape and an inclined part 52b that approaches the rotation axis CX as it goes vertically upward from the upper end of the tubular part 52a. The inclined part 52b is located vertically above the inclined part 47b of the inner guard 41, and provided so as to overlap the inclined part 47b in the vertical direction. The tubular part 52a is accommodated in an annular inside recovery groove 50. The inside recovery groove 50 is a groove formed by the first guide part 47, the middle wall part 48, and the bottom part 44.

In the state where only the guards 42, 43 are raised, the processing liquid from the peripheral edge of the substrate W is received by the inner peripheral surface of the second guide part 52, flows down along the inner peripheral surface, and is received by the inside recovery groove 50.

The processing liquid separation wall 53 has a cylindrical shape, and an upper end thereof is connected to the second guide part 52. The processing liquid separation wall 53 is accommodated in the annular outside recovery groove 51. The outside recovery groove 51 is a groove formed by the middle wall part 48, the outer wall part 46, and the bottom part 44.

The outer guard 43 is located outside the middle guard 42, and has a function as a third guide part that guides the processing liquid to the outside recovery groove 51. The outer guard 43 integrally includes a cylindrical tubular part 43a and an inclined part 43b approaching the rotation axis CX as it goes vertically upward from the upper end of the tubular part 43a. The tubular part 43a is accommodated in the outside recovery groove 51, and the inclined part 43b is located vertically above the inclined part 52b and provided so as to vertically overlap the inclined part 52b.

In the state where only the outer guard 43 is raised, the processing liquid from the peripheral edge of the substrate W is received by the inner peripheral surface of the outer guard 43, flows down along the inner peripheral surface, and is received by the outside recovery groove 51.

The inside recovery groove 50 and the outside recovery groove 51 are connected to a recovery mechanism (not illustrated) that recovers the processing liquid in a recovery tank provided outside the processing unit 1.

The guards 41 to 43 can be ascended and descended by a guard ascending and descending mechanism 55. The guard ascending and descending mechanism 55 ascends and descends the guards 41 to 43 between a guard processing position and a guard standby position such that the guards 41 to 43 do not collide with each other. The guard processing position is a position where the upper-end peripheral edge portion of the target guard to be ascended and descended is located above the upper surface of the substrate W, and the guard standby position is a position where the upper-end peripheral edge portion of the target guard is located below the upper surface 21a of the spin base 21. At this point, the upper-end peripheral edge portion is an annular portion that forms an upper-end opening of the target guard. In the example of FIG. 3, the guards 41 to 43 are located at the guard standby position. For example, the guard ascending and descending mechanism 55 includes a ball screw mechanism and a motor or an air cylinder.

A partition plate 15 is provided so as to vertically partition an inside space of the chamber 10 around the guard part 40. A through-hole and a notch (not illustrated) penetrating in the thickness direction of the partition plate 15 may be formed, and in the first embodiment, a through-hole passing the nozzle support column 33, the nozzle support column 63, and the nozzle support column 68 is made. An outer peripheral end of the partition plate 15 is connected to the side wall 11 of the chamber 10. An inner peripheral edge of the partition plate 15 surrounding the guard part 40 is formed in a circular shape having a diameter larger than the outer diameter of the outer guard 43. Accordingly, the partition plate 15 does not obstruct the ascent and descent of the outer guard 43.

In the example of FIG. 3, an exhaust duct 18 is provided in a part of the side wall 11 of the chamber 10 and in the vicinity of the floor wall 13. The exhaust duct 18 is communicably connected to an exhaust mechanism (not illustrated). In the clean air flowing down in the chamber 10, the air passing between the guard part 40 and the partition plate 15 is discharged from the exhaust duct 18 to the outside of the apparatus.

The camera 70 is used to monitor the state of a monitoring target in the chamber 10. For example, the monitoring target includes at least one of the substrate holder 20, the first nozzle 30, the second nozzle 60, the third nozzle 65, and the guard part 40. The camera 70 captures an image of an imaging region including the monitoring target to generate captured image data (hereinafter, simply referred to as a captured image), and outputs the captured image to the controller 9. As will be described in detail later, the controller 9 monitors the state of the monitoring target based on the captured image.

The camera 70 includes a solid-state imaging element such as a charge coupled device (CCD) or a complementary metal oxide semiconductor (CMOS) and an optical system such as a lens. In the example of FIG. 3, the camera 70 is installed at an imaging position vertically above the substrate W held by the substrate holder 20. In the example of FIG. 3, the imaging position is set vertically above the partition plate 15 and radially outside with respect to the guard part 40. At this point, the radial direction is the radial direction with respect to the rotation axis CX.

In the example of FIG. 3, a concave part (hereinafter, referred to as a recessed wall part 111) accommodating the camera 70 is formed on the side wall 11 of the chamber 10. The recessed wall part 111 has a shape recessed outward with respect to other parts of the side wall 11. The camera 70 is accommodated inside the recessed wall part 111. In the example of FIG. 3, a transparent member 72 is provided in front of the camera 70 in an imaging direction. The transparent member 72 has high translucency with respect to a wavelength of light detected by the camera 70. For this reason, the camera 70 can capture the image of the imaging region in the processing space through the transparent member 72. For example, transmittance of the transparent member 72 in the detection wavelength range of the camera 70 is equal to or greater than 60%, preferably equal to or greater than 80%. For example, the transparent member 72 is made of a transparent material such as quartz glass. In the example of FIG. 3, the transparent member 72 has a plate shape, and forms an accommodation space of the camera 70 together with the recessed wall part 111 of the side wall 11. When the transparent member 72 is provided, the camera 70 can be protected from the processing liquid and a volatile component of the processing liquid in the processing space.

For example, the imaging region of the camera 70 includes parts of the substrate holder 20 and the guard part 40. In the example of FIG. 3, the camera 70 captures the image of the imaging region obliquely downward from the imaging position. In other words, the imaging direction of the camera 70 is inclined vertically downward from the horizontal direction.

In the example of FIG. 3, an illumination part 71 is provided at a position vertically above the partition plate 15. As a specific example, the illumination part 71 is also provided inside the recessed wall part 111. In the case where the inside of the chamber 10 is a dark room, the controller 9 may control the illumination part 71 such that the illumination part 71 irradiates the imaging region when the camera 70 captures the image. Illumination light from the illumination part 71 is transmitted through the transparent member 72 and emitted into the processing space.

A hardware configuration of the controller 9 is the same as that of a general computer. That is, the controller 9 includes a data processing part such as a CPU that performs various kinds of arithmetic processing, a non-temporary storage part such as a read only memory (ROM) that is a read-only memory storing a basic program, and a temporary storage part such as a random access memory (RAM) that is a readable and writable memory storing various kinds of information. When the CPU of the controller 9 executes a predetermined processing program, each operation mechanism of the substrate processing apparatus 100 is controlled by the controller 9, and the processing in the substrate processing apparatus 100 proceeds. The controller 9 may be implemented by a dedicated hardware circuit that does not need software implementing a function of the controller 9.

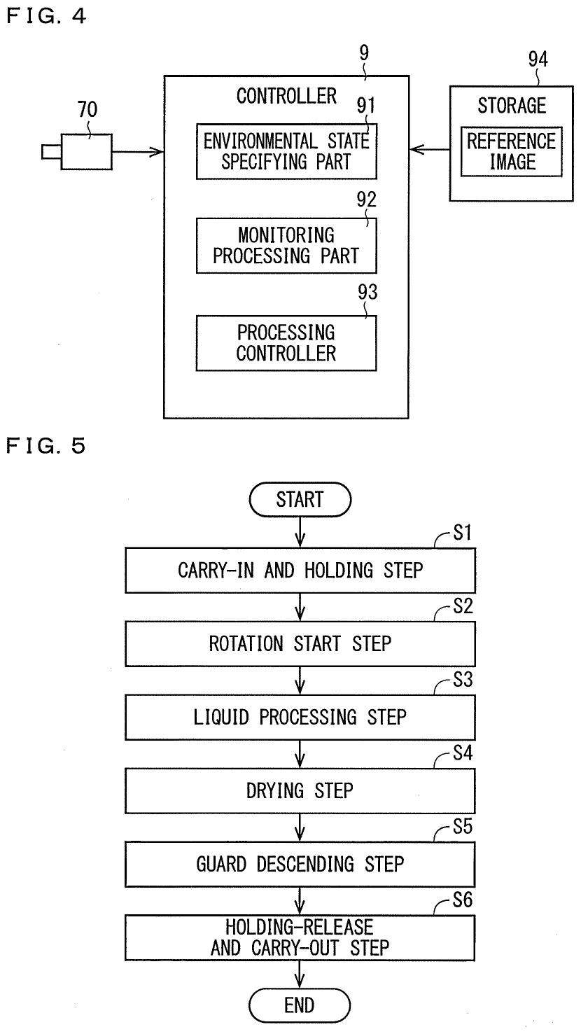

FIG. 4 is a functional block diagram schematically illustrating an example of an internal configuration of the controller 9. As illustrated in FIG. 4, the controller 9 includes an environmental state specifying part 91, a monitoring processing part 92, and a processing controller 93.

The processing controller 93 controls each component of the processing unit 1. More specifically, the processing controller 93 controls the spin motor 22, various valves such as and the valve 35, the arm driving motor that rotates each of the nozzle support columns 33, 63, 68, the guard ascending and descending mechanism 55, the fan filter unit 14, and the camera 70. The processing controller 93 controls these configurations according to a predetermined procedure, so that the processing unit 1 can perform processing on the substrate W.

### <Example of Flow of Substrate Processing>

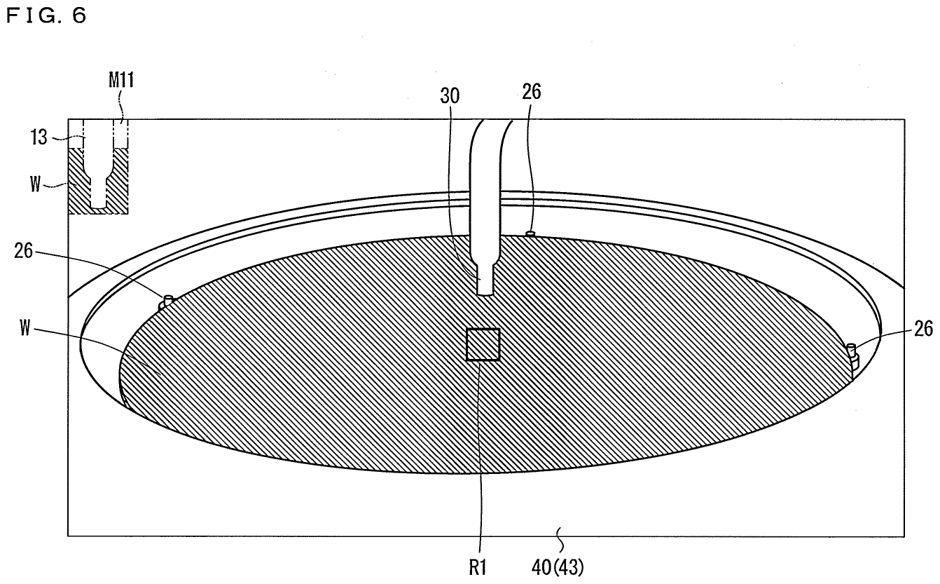

An example of a specific flow of processing for the substrate W will be briefly described below. FIG. 5 is a flowchart illustrating an example of a flow of substrate processing. Initially, the guards 41 to 43 stop at the guard standby position, and the nozzles 30, 60, 65 stop at the nozzle standby position. Although the controller 9 controls each configuration to execute a predetermined operation to be described later, each configuration itself will be adopted and described below as a subject of the operation.

First, the main conveyance robot 103 carries the unprocessed substrate W in the processing unit 1, and the substrate holder 20 holds the substrate W (step S1: carry-in and holding process). Because the guard part 40 is initially stopped at the guard standby position, collision between a hand of the main conveyance robot 103 and the guard part 40 can be avoided when the substrate W is carried in. When the substrate W is passed to the substrate holder 20, the plurality of chuck pins 26 move to the respective holding positions, whereby the plurality of chuck pins 26 holds the substrate W.

Subsequently, the spin motor 22 starts the rotation of the substrate W (step S2: rotation start step). Specifically, the spin motor 22 rotates the spin base 21 to rotate the substrate W held by the substrate holder 20.

Subsequently, the processing unit 1 performs various kinds of liquid processing on the substrate W (step S3: liquid processing step). For example, the processing unit 1 performs chemical liquid processing. First, the guard ascending and descending mechanism 55 ascends the guard corresponding to the chemical liquid in the guards 41 to 43 to the guard processing position. The guard for the chemical liquid is not particularly limited, but for example, may be the outer guard 43. In this case, the guard ascending and descending mechanism 55 stops the inner guard 41 and the middle guard 42 at the guard standby positions, and ascends the outer guard 43 to the guard processing position.

Subsequently, the processing unit 1 supplies the chemical liquid to the substrate W. At this point, it is assumed that the first nozzle 30 supplies the processing liquid. Specifically, the arm driving motor moves the first nozzle 30 to the nozzle processing position, and the valve 35 is open to discharge the chemical liquid from the first nozzle 30 toward the substrate W. Consequently, the chemical liquid spreads over the upper surface of the rotating substrate W and scatters from the peripheral edge of the substrate W. At this point, the chemical liquid acts on the upper surface of the substrate W, and the processing (for example, cleaning processing) corresponding to the chemical liquid is performed on the substrate W. The chemical liquid scattered from the peripheral edge of the substrate W is received by the inner peripheral surface of the guard part 40 (for example, the outer guard 43). When the chemical liquid processing is sufficiently performed, the processing unit 1 stops the supply of the chemical liquid.

Subsequently, the processing unit 1 performs rinse processing on the substrate W. The guard ascending and descending mechanism 55 adjusts an ascending and descending state of the guard part 40 as necessary. That is, when the guard for the rinse liquid is different from the guard for the chemical liquid, the guard ascending and descending mechanism 55 moves the guard corresponding to the rinse liquid in the guards 41 to 43 to the guard processing position. The guard for the rinse liquid is not particularly limited, but may be the inner guard 41. In this case, the guard ascending and descending mechanism 55 ascends the guards 41 to 43 to the respective guard processing positions.

Subsequently, the first nozzle 30 discharges the rinse liquid toward the upper surface of the substrate W. For example, the rinse liquid is the pure water. The first rinse liquid spreads over the upper surface of the rotating substrate W, and scatters from the peripheral edge of the substrate W while pushing away the chemical liquid on the substrate W. The processing liquid (mainly the rinse liquid) scattered from the peripheral edge of the substrate W is received by the inner peripheral surface of the guard part 40 (for example, the inner guard 41). When the rinse processing is sufficiently performed, the processing unit 1 stops the supply of the rinse liquid.

The processing unit 1 may supply a volatile rinse liquid such as isopropyl alcohol having high volatility to the substrate W as necessary. When the guard for the volatile rinse liquid is different from the above-described guard for the rinse liquid, the guard ascending and descending mechanism 55 may move the guard corresponding to the volatile rinse liquid in the guards 41 to 43 to the guard processing position. When the rinsing processing is completed, the first nozzle 30 moves to the nozzle standby position.

Subsequently, the processing unit 1 performs drying processing on the substrate W (step S4: drying step). For example, the spin motor 22 increases the rotation speed of the substrate W to dry the substrate W (what is called spin dry). Also in the drying processing, the processing liquid scattered from the peripheral edge of the substrate W is received by the inner peripheral surface of the guard part 40. When the drying processing is sufficiently performed, the spin motor 22 stops the rotation of the substrate W.

Subsequently, the guard ascending and descending mechanism 55 descends the guard part 40 to the guard standby position (step S5: guard descending step). That is, the guard ascending and descending mechanism 55 descends each of the guards 41 to 43 to the guard standby position.

Subsequently, the substrate holder 20 releases the holding of the substrate W, and the main conveyance robot 103 takes out the processed substrate W from the processing unit 1 (step S6: holding-release and carry-out step). The guard part 40 is stopped at the guard standby position when the substrate W is carried out, so that the collision between the hand of the main conveyance robot 103 and the guard part 40 can be avoided.

As described above, the various components in the processing unit 1 are appropriately operated to process the substrate W. For example, the substrate holder 20 holds or releases the substrate W. The first nozzle 30 moves between the nozzle processing position and the nozzle standby position, and discharges the processing liquid toward the substrate W at the nozzle processing position. Each of the guards 41 to 43 of the guard part 40 moves to a height position corresponding to each step.

### <Monitoring Processing>

When these components cannot be appropriately operated, the processing for the substrate W becomes inappropriate. Accordingly, in the first embodiment, the processing unit 1 monitors at least one of the above-described components as a monitoring target.

### <Monitoring of Position of Nozzle>

For example, when the first nozzle 30 cannot be moved to the nozzle processing position due to abnormality of the arm driving motor or the like, the processing of the substrate W becomes inappropriate. Accordingly, first, the case where the processing unit 1 monitors the position of the first nozzle 30 will be described.

In the above-described example, the first nozzle 30 moves to the nozzle processing position while the substrate holder 20 holds the substrate W (step S3). However, sometimes the first nozzle 30 moves to the nozzle processing position while the substrate holder 20 does not hold the substrate W.

For example, when the processing unit 1 processes many substrates W, impurities may accumulate in various components in the chamber 10. For example, the impurities in the processing liquid may be deposited and accumulated on the inner peripheral surface of the guard part 40. Accordingly, chamber cleaning processing cleaning the inside of the chamber 10 is appropriately performed.

In this chamber cleaning processing, the first nozzle 30 moves to the nozzle processing position while the substrate holder 20 does not hold the substrate W, and the first nozzle 30 may discharge a cleaning liquid (for example, pure water). When the spin motor 22 rotates the spin base 21, the cleaning liquid landed on the upper surface 21a of the spin base 21 spreads and scatters from the peripheral edge of the spin base 21, and collides with the inner peripheral surface of the guard part 40. Consequently, the inner peripheral surface of the guard part 40 can be cleaned with the cleaning liquid.

During cleaning the guard part 40, when the first nozzle 30 cannot move to the nozzle processing position due to the abnormality of the arm driving motor or the like, the guard part 40 cannot be properly cleaned. Accordingly, also in this cleaning processing, the processing unit 1 may monitor the position of the first nozzle 30.

Sometimes preparation processing (also referred to as a preprocessing) is executed before the liquid processing step (step S3) for the substrate W. In this preprocessing, sometimes the first nozzle 30 discharges the processing liquid from the nozzle processing position while the substrate holder 20 does not hold the substrate W. Also in this case, the processing unit 1 may monitor the position of the first nozzle 30.

During maintenance, sometimes the first nozzle 30 moves to the nozzle processing position while the substrate holder 20 does not hold the substrate W. Also in this case, the processing unit 1 may monitor the position of the first nozzle 30.

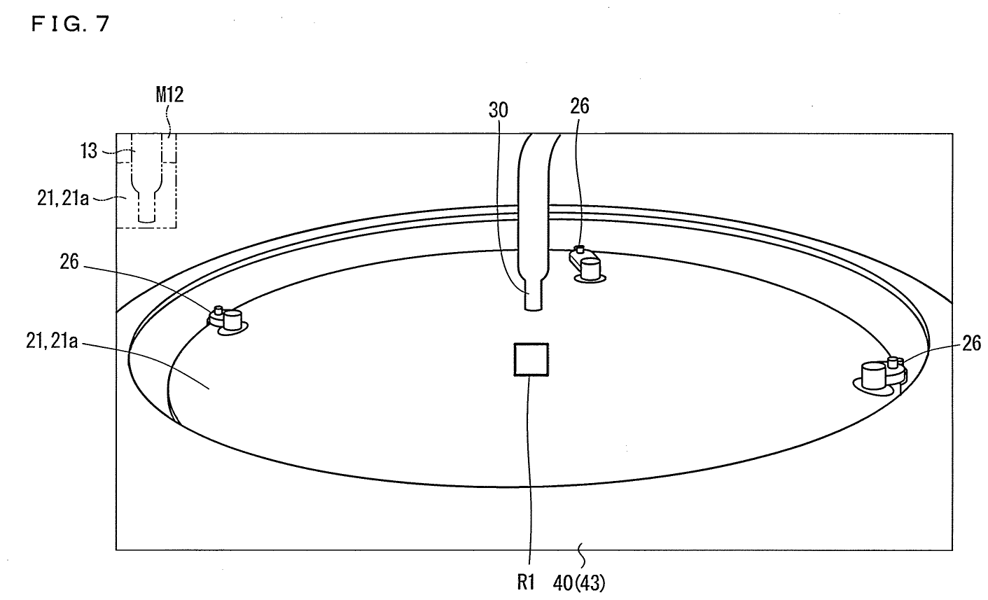

FIGS. 6 and 7 are views schematically illustrating an example of the captured image captured by the camera 70. In the examples of FIGS. 6 and 7, the entire upper-end peripheral edge of the outer guard 43 is included in the captured image. That is, the camera 70 is installed such that the entire upper-end peripheral edge of the outer guard 43 is included in the imaging region. At this point, because the camera 70 captures the image of the imaging region obliquely downward, the upper-end peripheral edge of the outer guard 43 having a circular shape in planar view has an elliptical shape in the captured image.

In the captured image of FIG. 6, the substrate holder 20 holds the substrate W, and the first nozzle 30 is located at the nozzle processing position. For example, the captured image of FIG. 6 is obtained by the camera 70 that captures the image of the imaging region while the first nozzle 30 does not yet discharge the processing liquid in the liquid processing step (step S3).

In the captured image of FIG. 7, the substrate holder 20 does not hold the substrate W, and the first nozzle 30 is located at the nozzle processing position. For example, the captured image of FIG. 7 is obtained by the camera 70 that captures the image of the imaging region while the first nozzle 30 does not yet discharge the processing liquid in any of the chamber cleaning processing, the preprocessing, and the maintenance.

As can be understood from FIGS. 6 and 7, the background region around a tip portion of the first nozzle 30 in the captured image differs depending on the existence or non-existence of the substrate W. Specifically, when the substrate W exists, the upper surface of the substrate W is included in the background region, and when the substrate W does not exist, the upper surface 21a of the spin base 21 is included in the background region instead of the substrate W.

As described above, the environmental state in the chamber 10 is not always the same but may change. The environmental state here can be expressed by the existence or non-existence, the position, and the shape of the object in the chamber 10 other than the monitoring target (in this case, the first nozzle 30). In the above-described example, the environmental state includes a substrate existence state (corresponding to a first environmental state) in which the substrate W exists in the chamber 10 and a substrate non-existence state (corresponding to a second environmental state) in which the substrate W does not exist in the chamber 10. In this case, the substrate existence state is a state in which the substrate W exists in the substrate holder 20, and the substrate non-existence state is a state in which the substrate W does not exist in the substrate holder 20.

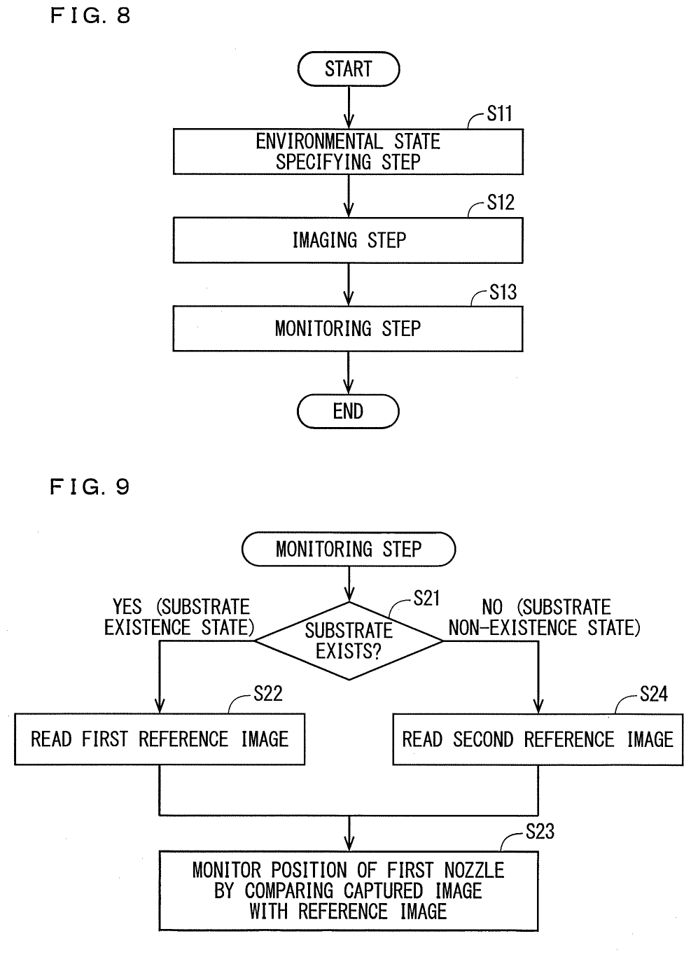

In the first embodiment, the controller 9 monitors the state of the monitoring target based on the captured image by a determination procedure according to the environmental state. FIG. 8 is a flowchart illustrating an example of a flowchart of the monitoring processing by the processing unit 1.

First, the environmental state specifying part 91 of the controller 9 specifies the environmental state (step S11: environmental state specifying step). Specifically, the environmental state specifying part 91 determines whether the environmental state is in the substrate existence state or the substrate non-existence state. For example, this determination is performed as follows.

The environmental state specifying part 91 may receive data indicating the presence or absence of the substrate W from the processing controller 93. For example, the processing controller 93 may control various configurations of the substrate processing apparatus 100 such that, when the main conveyance robot 103 carries the substrate W into the processing unit 1, the processing controller 93 provides data indicating that the substrate W exists in the chamber 10 to the environmental state specifying part 91, and when the main conveyance robot 103 carries the substrate W out of the processing unit 1, the processing controller 93 provides data indicating that the substrate W does not exist in the chamber 10 to the environmental state specifying part 91. The environmental state specifying part 91 may determine whether the environmental state is in the substrate existence state or the substrate non-existence state based on these data.

Alternatively, a sensor that detects the substrate W may be provided in the chamber 10. The environmental state specifying part 91 may determine whether the environmental state is in the substrate existence state or the substrate non-existence state based on the detection result of the sensor.

Subsequently, the camera 70 captures the image of the imaging region to generate the captured image, and outputs the captured image to the controller 9 (step S12: imaging step). When the imaging step is performed in the liquid processing step, the captured image of FIG. 6 is obtained as described above. When the imaging step is performed in any of the chamber cleaning processing, the preprocessing, and the maintenance, the captured image of FIG. 7 is obtained as described above.

The environmental state specifying part 91 may specify the environmental state based on the captured image captured by the camera 70. In this case, the environmental state specifying step is executed after the imaging step. As illustrated in FIGS. 6 and 7, the substrate determination region R1 may be set in the captured image. The substrate determination region R1 is a region including at least a part of the substrate W in the captured image of FIG. 6. The position and size of the substrate determination region R1 are not particularly limited, but the region is a region corresponding to a central portion of the substrate W in the example of FIG. 6. A pixel value in the substrate determination region R1 varies depending on the existence or non-existence of the substrate W. Accordingly, the environmental state specifying part 91 can determine the existence or non-existence of the substrate W based on the pixel value in the substrate determination region R1. For example, the environmental state specifying part 91 may determine that the substrate W exists when a statistical value (for example, an average value) of the pixel values in the substrate determination region R1 falls within a predetermined range. Alternatively, the substrate determination region R1 of the captured image is stored in the storage 94 as a reference image when the substrate W does not exist, and the environmental state specifying part 91 may compare the reference image with the substrate determination region R1 to determine the existence or non-existence of the substrate W. For example, the storage 94 is a nonvolatile memory.

Subsequently, the monitoring processing part 92 monitors the state of the monitoring target based on the captured image captured by the camera 70 by a determination procedure according to the environmental state specified by the environmental state specifying part 91 (step S13: monitoring step). That is, when the environmental state is in the first environmental state (in this case, the substrate existence state), the monitoring processing part 92 uses a first determination procedure corresponding to the first environmental state. On the other hand, when the environmental state is the second environmental state (in this case, the substrate non-existence state) different from the first environmental state, the monitoring processing part 92 uses a second determination procedure corresponding to the second environmental state and different from the first determination procedure.

FIG. 9 is a flowchart illustrating a specific example of the monitoring step. First, the monitoring processing part 92 determines the existence or non-existence of the substrate W in the captured image (step S21). The monitoring processing part 92 can recognize the existence or non-existence of the substrate W based on the environmental state specified by the environmental state specifying part 91.

When the substrate W exists, namely, when the environmental state is in the substrate existence state, the monitoring processing part 92 reads the first reference image data (hereinafter, simply referred to as a reference image) M11 from the storage 94 (step S22). As illustrated in FIG. 6, first reference image M11 is an image having a size smaller than the size of the captured image. The first reference image M11 includes the tip portion of the first nozzle 30, and the substrate W is included in the background region around the tip portion. For example such the first reference image M11 is obtained as follows. That is, in the state where the substrate holder 20 holds the substrate W while the first nozzle 30 is located at the nozzle processing position, the camera 70 captures the image of the imaging region to generate the captured image. Then, the controller 9 generates the first reference image M11 by cutting out a partial region including the tip portion of the first nozzle 30 from the captured image. The first reference image M11 is previously stored in the storage 94. For example, the storage 94 is a non-volatile non-transitory memory.

Subsequently, the monitoring processing part 92 monitors the position of the first nozzle 30 by comparing the captured image from the camera 70 with the read reference image (in this case, the first reference image M11) (step S23). More specifically, first, the monitoring processing part 92 detects the position of the first nozzle 30 by matching processing between the captured image and the first reference image M11. For example, the matching processing includes template matching. As a specific example, the monitoring processing part 92 scans the first reference image M11 in the captured image, and detects the position where a similarity ratio between the first reference image M11 and each partial region in the captured image becomes the highest as the position of the first nozzle 30. The similarity ratio is not particularly limited, but for example, may be a known similarity ratio such as a sum of squared differences of pixel values, a sum of absolute differences of pixel values, normalization cross-correlation, or zero-mean normalization cross-correlation.

The monitoring processing part 92 may determine whether the detection position of the first nozzle 30 falls within a predetermined position range. The monitoring processing part 92 may determine that the position of the first nozzle 30 is normal when the detection position falls within the predetermined position range, and determine that the abnormality related to the position of the first nozzle 30 is generated when the detection position is located outside the predetermined position range.

On the other hand, when the substrate W does not exist, namely, when the environmental state is in the substrate non-existence state, the monitoring processing part 92 reads a second reference image M12 from the storage 94 (step S24). As illustrated in FIG. 7, the second reference image M12 is also an image smaller in size than the captured image. The second reference image includes the tip portion of the first nozzle 30, and the upper surface 21a of the spin base 21 is included in the background region around the tip portion instead of the substrate W. For example, such the second reference image M12 is obtained as follows. That is, in the state where the substrate holder 20 does not hold the substrate W while the first nozzle 30 is located at the nozzle processing position, the camera 70 captures the image of the imaging region to generate the captured image. Then, the controller 9 cuts out a partial region including the tip portion of the first nozzle 30 from the captured image to generate the second reference image M12. The second reference image M12 is previously stored in the storage 94. That is, a plurality of reference images (in this case, the first reference image M11 and the second reference image M12) according to the environmental state are previously stored in the storage 94.

Subsequently, the monitoring processing part 92 monitors the position of the first nozzle 30 by comparing the captured image from the camera 70 with the read reference image (in this case, the second reference image M12) (step S23). More specifically, the monitoring processing part 92 detects the position of the first nozzle 30 by the matching processing between the captured image and the second reference image M12. The monitoring processing part 92 may determine that the position of the first nozzle 30 is normal when the detection position of the first nozzle 30 falls within a predetermined position range, and determine that the abnormality related to the position of the first nozzle 30 is generated when the detection position is located outside the predetermined position range.

As described above, the monitoring processing part 92 monitors the state of the monitoring target (in this case, the first nozzle 30) based on the comparison between the captured image and the reference image corresponding to the environmental state. Specifically, when the environmental state is the substrate existence state, namely, when the substrate W exists in the imaging region, the first reference image M11 is used. In the substrate existence state, the substrate W is also included in the background region of the captured image, and the substrate W is also included in the background region of the first reference image M11. For this reason, the similarity ratio between each partial region of the captured image and the first reference image M11 is hardly affected by the substrate W in the background region.

The case where the second reference image M12 is adopted when the environmental state is the substrate existence state will be described for comparison. Because the background region of the second reference image M12 includes the upper surface 21a of the spin base 21, the similarity ratio between each partial region of the captured image and the second reference image M12 is affected by the difference in the background region even when the regions indicating the first nozzle 30 are completely matched with each other between the partial region and the second reference image M12. That is, in the matching processing between the captured image and second reference image M12, the difference in the background region can be an error factor of the position detection.

On the other hand, when the environmental state is the substrate existence state, the similarity ratio is hardly affected by the background region using the first reference image M11. Accordingly, the monitoring processing part 92 can detect the position of the first nozzle 30 with higher accuracy.

Similarly, when the environmental state is in the substrate non-existence state, the monitoring processing part 92 can detect the position of the first nozzle 30 with higher accuracy by performing the matching processing between the captured image and the second reference image M12.

As described above, in the first embodiment, when the processing unit 1 monitors the predetermined state (in this case, the position of the first nozzle 30) of the monitoring target, the controller 9 uses the determination procedure according to the environmental state in the imaging region. In other words, when detecting a certain kind of abnormality related to the monitoring target, the controller 9 varies the determination procedure according to the environmental state. Consequently, even when the environmental state is the first environmental state or the second environmental state, the controller 9 can monitor the state of the monitoring target with higher accuracy.

In the above-described example, the existence or non-existence of the substrate W has been described, but the present embodiment is not necessarily limited thereto. In short, the environmental state specifying part 91 and the monitoring processing part 92 may operate as follows.

That is, the environmental state specifying part 91 determines the existence or non-existence of the object (in this case, the substrate W) around the monitoring target (in this case, the first nozzle 30) in the imaging region to specify the environmental state. That is, the environmental state specifying part 91 determines whether the environmental state is in an object existence state or an object non-existence state. When the environmental state is in the object existence state, the monitoring processing part 92 reads the first reference image (in this case, the first reference image M11) including the object and the monitoring target from the storage 94, and monitors the state of the monitoring target by comparing the first reference image with the captured image from the camera 70. In addition, when the environmental state is in the object non-existence state, the monitoring processing part 92 reads the second reference image (in this case, the second reference image M12) including the monitoring target without including the object from the storage 94, and monitors the state of the monitoring target by comparing the second reference image with the captured image from the camera 70. Consequently, the monitoring processing part 92 can monitor the state of the monitoring target with high accuracy in both the object existence state and the object non-existence state.

### <Specification of Environmental State>

In the above-described example, the environmental state specifying part 91 specifies the environmental state based on the data from the processing controller 93, the detection result from a separately provided sensor, or the captured image from the camera 70. As described above, although the environmental state specifying part 91 may use the data of the processing controller 93, reliability of the data is not always high. This is because even when the processing controller 93 controls various components of the substrate processing apparatus 100, sometimes the various components do not operate normally due to the abnormality. In this case, the reliability of the data from the processing controller 93 becomes lower.

On the other hand, when the detection result of the sensor or the captured image of the camera 70 is used, the environmental state specifying part 91 can directly check the environmental state, so that the environmental state can be specified with higher accuracy. In the case of using the captured image, the sensor different from the camera 70 is not required, so that the increase in manufacturing cost of the processing unit 1 can also be avoided.

The environmental state specifying part 91 may specify the environmental state using the learned model. For example, the learned model is a model (algorithm) generated based on a machine learning algorithm such as deep learning. The learned model classifies the input captured image into one of the following two first environment category and second environment category. The first environment category is a category corresponding to the first environmental state, and in the above-described example, is a category indicating that the substrate W exists in the substrate holder 20. The second environmental category is a category corresponding to the second environmental state, and in the above-described example, is a category indicating that the substrate W of the substrate holder 20 does not exist. For example, such the learned model is generated by causing the learning model to learn teacher data in which a correct category (label) is associated with a plurality of pieces of learning data.

### <Discharge Monitoring of Nozzle>

Subsequently, the case where the processing unit 1 monitors a discharge state of the first nozzle 30 will be described. Sometimes the droplet of the processing liquid falls from the discharge port of the first nozzle 30 (what is called dripping). For example, when the discharge of the processing liquid from the first nozzle 30 is stopped, the droplet of the processing liquid may fall from the first nozzle 30. When such the droplet falls on the upper surface of the substrate W, a problem may be generated. For this reason, in this case, the controller 9 monitors the discharge state of the processing liquid from the first nozzle 30 based on the captured image.

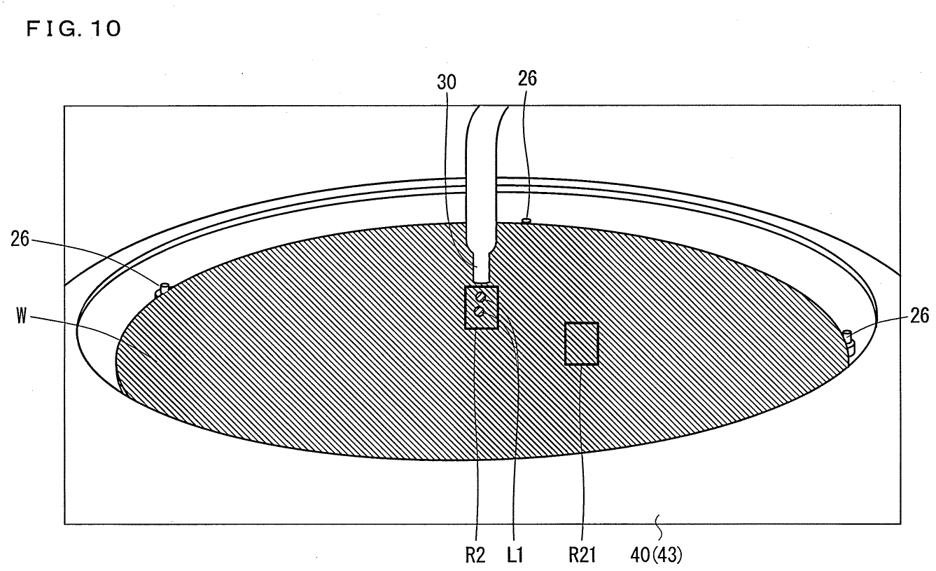

FIG. 10 is a view schematically illustrating an example of the captured image when a droplet L1 of the processing liquid falls from the discharge port of the first nozzle 30. The captured image of FIG. 10 includes a plurality of droplets L1 immediately below the lower end of the first nozzle 30 located at the nozzle processing position. In the example of FIG. 10, a discharge determination region R2 is also illustrated. The discharge determination region R2 is set as a region that is located immediately below the lower end of the first nozzle 30 and contains the processing liquid discharged from the first nozzle 30 in the captured image. The discharge determination region R2 is set to be larger than the droplet L1. As illustrated in FIG. 10, the discharge determination region R2 also includes the upper surface of the substrate W. In the example of FIG. 10, the upper surface of the substrate W is substantially uniform.

The pixel value in the discharge determination region R2 during generation of the droplet L1 is different from the pixel value in the discharge determination region R2 during no generation of the droplet L1, so that the existence or non-existence of the droplet L1 can be determined based on the pixel value in the discharge determination region R2.

For example, when the droplet L1 is not generated, each pixel value in the discharge determination region R2 is substantially uniform because each pixel value becomes a value corresponding to the substantially uniform upper surface of the substrate W. That is, variation in the pixel value in the discharge determination region R2 is small. On the other hand, the variation in the pixel value in the discharge determination region R2 becomes large when the droplet L1 is generated.

On the upper surface of the substrate W, sometimes various patterns such as metal, a semiconductor, and an insulator are formed to form a circuit pattern. When light is incident on the upper surface of the substrate W, the light is reflected according to the pattern on the upper surface of the substrate W. For this reason, the variation in a luminance value increases in the luminance distribution on the upper surface of the substrate W.

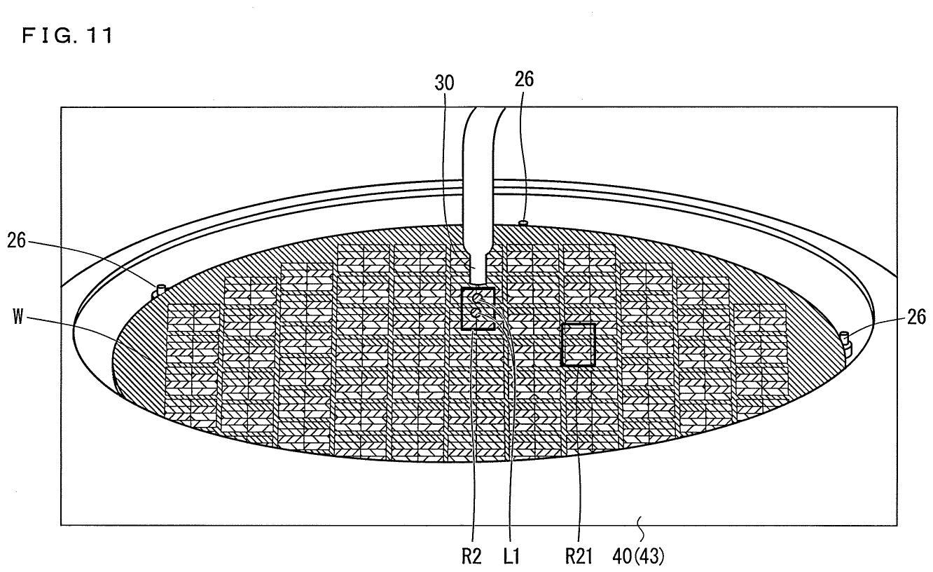

FIG. 11 is a view schematically illustrating an example of the captured image when the droplet L1 of the processing liquid falls from the discharge port of the first nozzle 30. However, in the captured image of FIG. 11, the pattern is formed on the upper surface of the substrate W. When a plurality of patterns are formed on the upper surface of the substrate W as illustrated in FIG. 11, the variation in the pixel value in the discharge determination region R2 increases even when a plurality of droplets L1 are not generated. This is because the light is reflected according to the pattern on the upper surface of the substrate W, and the variation in the luminance value on the upper surface of the substrate W increases. In the example of FIG. 11, a state of the reflection of the light is schematically illustrated by a rectangular block with hatching.

As described above, the substrate W carried into the processing unit 1 includes a pattern substrate having the plurality of fine patterns formed on the upper surface of the substrate W, and a uniform substrate having a uniform upper surface as compared with the pattern substrate. In other words, the environmental state includes a patterned substrate state (corresponding to the first environmental state) in which the plurality of patterns are formed on the upper surface of the substrate W and a uniform substrate state (corresponding to the second environmental state) in which few patterns are formed on the upper surface of the substrate W.

When the environmental state is the uniform substrate state, because the upper surface of the substrate W is uniform, the variation in the pixel value in the discharge determination region R2 is small when the droplet L1 is not generated. On the other hand, the variation increases when the droplet L1 is generated. For this reason, when an index (hereinafter, referred to as a variation index) indicating the variation, the existence or non-existence of the droplet L1 can be determined based on the variation index.

On the other hand, when the environmental state is the patterned substrate state, even if the droplet L1 is not generated, the variation in the pixel value in the discharge determination region R2 is large. For this reason, the determination accuracy decreases in the determination based on the variation index.

Accordingly, in the processing of monitoring the discharge state of the first nozzle 30, the monitoring processing part 92 varies the determination algorithm according to the patterned substrate state and the uniform substrate state.

An example of the processing of monitoring the discharge state of the first nozzle 30 is similar to the flowchart of FIG. 8. First, in step S11, the environmental state specifying part 91 determines whether the environmental state is the patterned substrate state or the uniform substrate state. As a specific example, the environmental state specifying part 91 may receive the substrate data indicating the existence or non-existence of the pattern of the substrate W from the processing controller 93. For example, the processing controller 93 can obtain the substrate data by input of an operator or an apparatus on the upstream side of the substrate processing apparatus 100. The processing controller 93 may give the substrate data to the environmental state specifying part 91 when the main conveyance robot 103 is controlled to carry the substrate W into the processing unit 1. The environmental state specifying part 91 may determine whether the environmental state is the patterned substrate state or the uniform substrate state based on the substrate data.

Alternatively, a sensor that detects the existence or non-existence of the pattern of the substrate W may be provided in the chamber 10. The environmental state specifying part 91 may determine whether the environmental state is the patterned substrate state or the uniform substrate state based on the data from the sensor.

Alternatively, the environmental state specifying part 91 may determine the existence or non-existence of the pattern of the substrate W based on the captured image captured by the camera 70. For example, when the substrate holder 20 receives the substrate W from the main conveyance robot 103, namely, in the holding and carry-in step (step S1), the camera 70 captures the image of the imaging region. The environmental state specifying part 91 receives the captured image from the camera 70, and for example, calculates the variation index in the substrate determination region R21 of the captured image. The substrate determination region R21 is set to the region including the upper surface of the substrate W held by the substrate holder 20. The substrate W is the pattern substrate when the variation index of the substrate determination region R21 is large, and the substrate W is the uniform substrate when the variation index of the substrate determination region R21 is small.

Accordingly, the environmental state specifying part 91 compares the variation index with a predetermined pattern threshold. For example, the pattern threshold is previously set by the simulation or experiment. The environmental state specifying part 91 determines that the pattern is formed on the substrate W when the variation index is equal to or more than the pattern threshold. In other words, the environmental state specifying part 91 determines that the environmental state is the patterned substrate state. On the other hand, when the variation index is less than the pattern threshold, the environmental state specifying part 91 determines that the pattern is not formed on the substrate W. In other words, the environmental state specifying part 91 determines that the environmental state is the uniform substrate state. The substrate determination region R1 may be used instead of the substrate determination region R21.

Subsequently, in step S12, the camera 70 captures the image of the imaging region during the liquid processing step (step S3) to generate the captured image, and outputs the captured image to the controller 9. In the liquid processing step, the camera 70 may repeatedly capture the image of the imaging region at predetermined time intervals. Consequently, the discharge state of the first nozzle 30 can be monitored over an entire period of the liquid processing step.

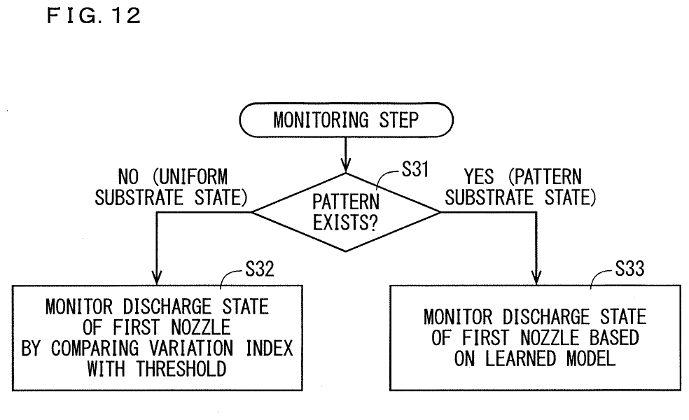

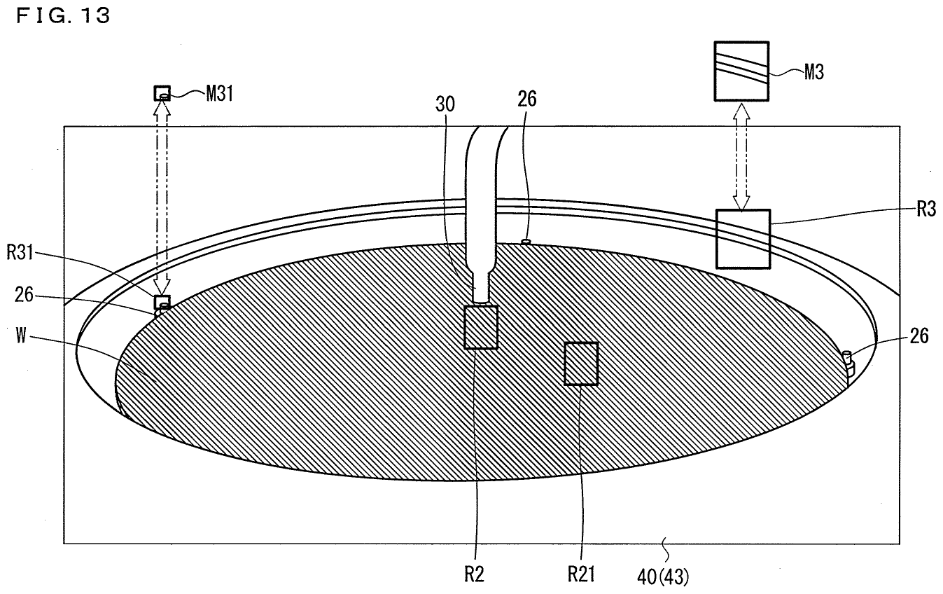

Subsequently, in step S13, the monitoring processing part 92 monitors the state of the monitoring target based on the captured image in a determination procedure according to the environmental state specified by the environmental state specifying part 91. That is, the monitoring processing part 92 determines the discharge state of the first nozzle 30 based on the captured image captured in the liquid processing step. FIG. 12 is a flowchart illustrating a specific example of the monitoring step.

First, the monitoring processing part 92 determines whether the pattern is formed on the upper surface of the substrate W in the discharge determination region R2 (step S31). The monitoring processing part 92 can recognize the existence or non-existence of the pattern based on the environmental state specified by the environmental state specifying part 91.

When the pattern is not formed on the substrate W, namely, when the environmental state is the uniform substrate state, the monitoring processing part 92 monitors the discharge state of the first nozzle 30 by comparing the variation index with a predetermined deviation threshold (step S32). Hereinafter, a specific description will be given.

First, the monitoring processing part 92 calculates the variation index of the pixel value in the discharge determination region R2 of the captured image (see FIG. 10). For example, the variation index may be a standard deviation. In the case where the environmental state is the uniform substrate state, the variation index is small when the droplet L1 is not generated, and the variation index is large when the droplet is generated.

Thus, the monitoring processing part 92 compares the variation index with the predetermined deviation threshold. For example, the deviation threshold is previously set by the simulation or experiment. The monitoring processing part 92 determines that the droplet L1 is generated when the variation index is equal to or larger than the deviation threshold. That is, the monitoring processing part 92 determines that the abnormality (in this case, dripping) related to the discharge state is generated. On the other hand, when the variation index is less than the deviation threshold, the monitoring processing part 92 determines that the droplet L1 is not generated. That is, the monitoring processing part 92 determines that the discharge state is normal.

On the other hand, when the pattern is formed on the substrate W, namely, when the environmental state is the patterned substrate state, the monitoring processing part 92 monitors the discharge state of the first nozzle 30 based on the learned model (step S33). Hereinafter, a specific description will be given.

For example, the learned model is the model (algorithm) generated based on the machine learning algorithm such as the deep learning. The learned model classifies the input captured image into one of the following two first category and second category. The first category indicates that the droplet L1 is not generated, and the second category indicates that the droplet L1 is generated. For example, such the learned model is generated by causing the learning model to learn teacher data in which a correct category (label) is associated with a plurality of pieces of learning data.

The monitoring processing part 92 inputs the captured image (see FIG. 11) captured by the camera 70 in the liquid processing step to the learned model. The monitoring processing part 92 determines the existence or non-existence of the droplet L1 by classifying the captured image by the learned model.

As described above, when the uniform upper surface of the substrate W is included in the discharge determination region R2 of the captured image, the monitoring processing part 92 monitors the discharge state of the first nozzle 30 by comparing the variation index with the deviation threshold. For this reason, the monitoring processing part 92 can monitor the discharge state by simpler processing. Specifically, the monitoring processing part 92 can determine the existence or non-existence of the droplet L1 by a simpler step. Accordingly, a load on the controller 9 can be reduced. Moreover, in the uniform substrate state, the determination accuracy using the comparison between the variation index and the deviation threshold is higher than the determination accuracy using the learned model.

On the other hand, when the discharge determination region R2 of the captured image includes the upper surface of the substrate W on which the pattern is formed, the monitoring processing part 92 monitors the discharge state of the first nozzle 30 based on the learned model. For this reason, even in the state where the pattern is formed on the upper surface of the substrate W, the monitoring processing part 92 can monitor the discharge state with higher accuracy.

### <Guard Monitoring>

The case where the processing unit 1 monitors the guard part 40 will be described below. As described above, the ascending and descending state of the guard part 40 differs according to each step. As an example, the case where the processing unit 1 monitors the height position of the outer guard 43 while only the outer guard 43 is located at the guard processing position will be described below.

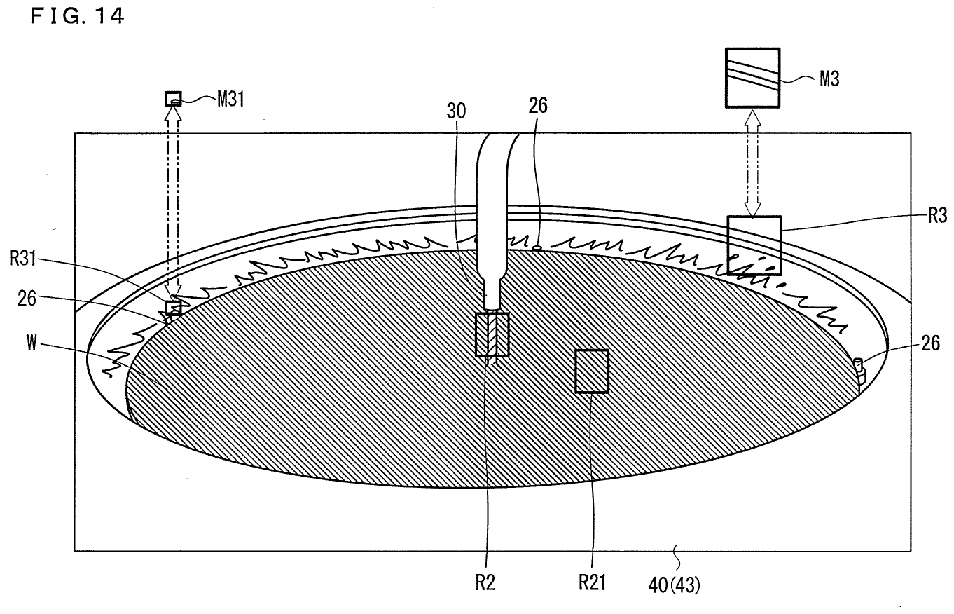

FIG. 13 is a view schematically illustrating an example of the captured image captured by the camera 70. In the captured image of FIG. 13, only the outer guard 43 is located at the guard processing position.

FIG. 13 also illustrates a guard determination region R3 used for the monitoring processing. The guard determination region R3 is a region used for determining the position of the outer guard 43. The guard determination region R3 is a region including at least a part of the outer guard 43 when normally located at the guard processing position, and in the example of FIG. 13, the guard determination region R3 is set to a region including a part of the upper-end peripheral edge of the outer guard 43. More specifically, the guard determination region R3 is set so as to include a part of the upper portion of the elliptical upper-end peripheral edge of the outer guard 43 in the captured image.

At this point, a reference image M3 is previously set. The reference image M3 is an image of the same region as the guard determination region R3, and is generated based on a normal captured image captured by the camera 70 when the outer guard 43 normally stops at the guard processing position. The reference image M3 is previously stored in the storage 94.

When the similarity ratio between the guard determination region R3 of the captured image and the reference image M3 is high, it is considered that the outer guard 43 is normally located at the guard processing position. Accordingly, as will be described in detail later, the monitoring processing part 92 calculates the similarity ratio between the guard determination region R3 and the reference image M3, and compares the similarity ratio with a predetermined guard threshold (corresponding to the threshold). When the similarity ratio is higher than the guard threshold, it is determined that the outer guard 43 is normally located at the guard processing position.

Meanwhile, when the camera 70 captures the image of the imaging region at a time point when the processing unit 1 does not yet supply the processing liquid to the substrate W, the captured image does not contain the processing liquid. Accordingly, the guard determination region R3 naturally does not contain the processing liquid.

On the other hand, when the processing unit 1 supplies the processing liquid to the rotating substrate W, the processing liquid scatters from the peripheral edge of the substrate W, and the scattered processing liquid adheres to the inner peripheral surface of the guard part 40. FIG. 14 is a view schematically illustrating an example of the captured image when the processing liquid scatters from the peripheral edge of the substrate W. In the captured image of FIG. 14, the liquid columnar processing liquid is discharged from the first nozzle 30, and the processing liquid spreads on the upper surface of the substrate W and scatters from the peripheral edge of the substrate W. A part of the scattered processing liquid is also included in the guard determination region R3.

As described above, sometimes there is the case where the processing liquid is supplied to the substrate W and scattered from the peripheral edge of the substrate W, or sometimes there is the case where the processing liquid is not yet supplied to the substrate W and not scattered from the substrate W. In other words, the environmental state includes a liquid existence state (corresponding to the first environmental state) in which the processing liquid scattering from the substrate W exists and a liquid non-existence state (corresponding to the second environmental state) in which the processing liquid does not exist. In the liquid existence state, the processing liquid collides with the inner peripheral surface of the outer guard 43, and in the liquid non-existence state, the processing liquid does not collide with the outer guard 43.

In the case where the processing liquid is included in the guard determination region R3, the similarity ratio between the guard determination region R3 and the reference image M3 may be low even when the outer guard 43 is normally located at the guard processing position. This is because the guard determination region R3 of the captured image contains the processing liquid, whereas the reference image M3 does not contain the processing liquid. In this case, even when the outer guard 43 is normally located in the guard processing position, the similarity ratio may fall below the guard threshold. When the similarity ratio falls below the guard threshold, the processing unit 1 erroneously detects the abnormality of the outer guard 43.

Accordingly, in the processing of monitoring the outer guard 43, the monitoring processing part 92 sets the guard threshold to a different value according to the liquid existence state and the liquid non-existence state.

An example of the processing of monitoring the height position of the outer guard 43 is similar to the flowchart of FIG. 8. That is, in step S11, the environmental state specifying part 91 determines whether the environmental state is the liquid existence state or the liquid non-existence state. As a specific example, the environmental state specifying part 91 may specify the environmental state based on the data from the processing controller 93. For example, the data indicating that the first nozzle 30 discharges the processing liquid at the nozzle processing position may be given from the processing controller 93 to the environmental state specifying part 91. The environmental state specifying part 91 may determine that the environmental state is the liquid existence state when receiving the data, and may determine that the environmental state is the liquid non-existence state when not receiving the data.

Alternatively, the environmental state specifying part 91 may specify the environmental state based on the captured image from the camera 70. In this case, step S11 is executed after step S12 (imaging step). For example, the environmental state specifying part 91 may determine whether the processing liquid is discharged based on the pixel value in the discharge determination region R2 of the captured image. The pixel value in the discharge determination region R2 during the discharge of the liquid columnar processing liquid from the first nozzle 30 is different from the pixel value in the discharge determination region R2 during no discharge of the processing liquid from the first nozzle 30, so that the environmental state specifying part 91 can determine whether the liquid columnar processing liquid is discharged based on the pixel value in the discharge determination region R2. For example, the environmental state specifying part 91 may determine that the liquid columnar processing liquid is discharged from the first nozzle 30 when the statistical value (for example, the sum) of the pixel values in the discharge determination region R2 falls within a predetermined liquid column range. In other words, the environmental state specifying part 91 may determine that the environmental state is the liquid existence state. The environmental state specifying part 91 may determine that the processing liquid is not discharged from the first nozzle 30 when the statistical value (for example, the sum) is located out of the predetermined liquid column range. In other words, the environmental state specifying part 91 may determine that the environmental state is the liquid non-existence state.

In step S12, the camera 70 captures the image of the imaging region to generate the captured image, and outputs the captured image to the controller 9. In this case, in the liquid processing step (step S3) in which the outer guard 43 is located at the guard processing position, the camera 70 may continue to capture the image of the imaging region. Consequently, the height position of the outer guard 43 can be monitored over the entire period of the liquid processing step.

In the liquid processing step, first, the processing controller 93 outputs a control signal moving the outer guard 43 to the guard processing position to the guard ascending and descending mechanism 55. The guard ascending and descending mechanism 55 moves the outer guard 43 to the guard processing position based on the control signal. Then, at a second point that is after a first point at which a sufficient time for the outer guard 43 to stop at the guard position elapses, the processing controller 93 opens the valve 35 to discharge the processing liquid from the first nozzle 30.

When the guard ascending and descending mechanism 55 operates normally, the outer guard 43 located at the guard processing position is included in the captured image obtained by capturing the image of the imaging region with the camera 70 after the first point. The case where the camera 70 performs the imaging after the first point will be described below.

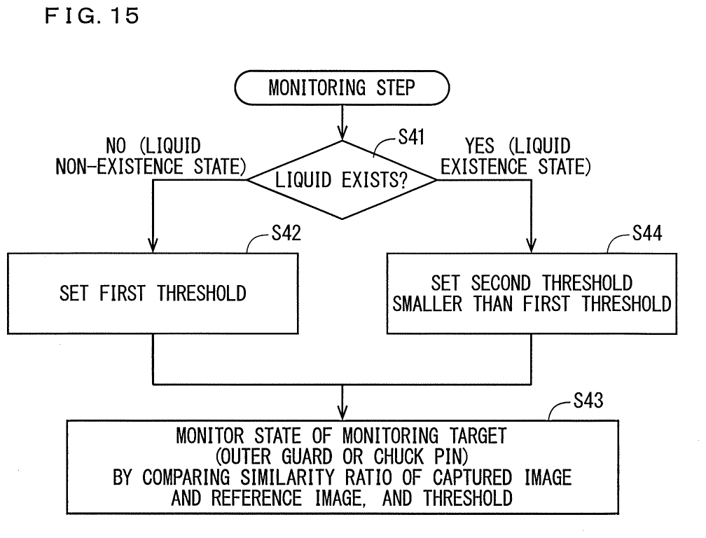

Subsequently, in step S13, the monitoring processing part 92 monitors the height position of the outer guard 43 based on the captured image in the determination procedure according to the environmental state specified by the environmental state specifying part 91. FIG. 15 is a flowchart illustrating a specific example of the monitoring step.

The monitoring processing part 92 determines whether the processing liquid is contained in the guard determination region R3 (step S41). The monitoring processing part 92 can recognize the existence or non-existence of the processing liquid based on the environmental state specified by the environmental state specifying part 91.

When the processing liquid does not exist, namely, when the environmental state is in the liquid non-existence liquid, the monitoring processing part 92 sets a first guard threshold (corresponding to the first threshold) as the guard threshold used for the monitoring of the outer guard 43 described later (step S42). The first guard threshold is a relatively large value, and for example, is previously set.

Subsequently, the monitoring processing part 92 calculates the similarity ratio between the guard determination region R3 of the captured image and the reference image M3, and monitors the position of the outer guard 43 by comparing the similarity ratio with the guard threshold (in this case, the first guard threshold) (step S43). The similarity ratio is not particularly limited, but may be a known similarity ratio such as a sum of squares of differences of pixel values, a sum of absolute values of differences of pixel values, normalized cross-correlation, or zero-mean normalized cross-correlation. When the similarity ratio between the guard determination region R3 and the reference image M3 is high, it is considered that the outer guard 43 normally stops at the guard processing position.

The monitoring processing part 92 determines that the outer guard 43 is normally located in the guard processing position when the similarity ratio is equal to or greater than the guard threshold, and determines that the abnormality is generated in the outer guard 43 when the similarity ratio is less than the guard threshold.

On the other hand, when the processing liquid exists, namely, when the environmental state is the liquid existence state, the monitoring processing part 92 sets a second guard threshold (corresponding to the second threshold) as the guard threshold (step S44). The second guard threshold is smaller than the first guard threshold, and for example, is previously set.

Subsequently, the monitoring processing part 92 monitors the position of the outer guard 43 by comparing the similarity ratio between the guard determination region R3 of the captured image and the reference image M3 with the guard threshold (in this case, the second guard threshold) (step S43). The monitoring processing part 92 determines that the outer guard 43 is normally located in the guard processing position when the similarity ratio is equal to or greater than the guard threshold, and the monitoring processing part 92 determines that the abnormality is generated in the outer guard 43 when the similarity ratio is less than the guard threshold.

As described above, when the processing liquid is not contained in the guard determination region R3 of the captured image, the larger first guard threshold is adopted as the guard threshold. For this reason, the monitoring processing part 92 can detect the abnormality of outer guard 43 with higher accuracy. That is, when the processing liquid that is a factor of decreasing the similarity ratio does not exist, the height position of the outer guard 43 is monitored more strictly using the large first card threshold as the guard threshold. Consequently, even the slight abnormality can be detected.

On the other hand, when the processing liquid is contained in the guard determination region R3 of the captured image, the second guard threshold smaller than the first guard threshold is adopted as the guard threshold. For this reason, erroneous detection of the abnormality caused by the processing liquid, which is the factor of decreasing the similarity ratio, can be reduced.

In the above example, the monitoring of the outer guard 43 has been described, but the same applies to the case where the monitoring target is the chuck pin 26. As illustrated in FIGS. 13 and 14, the captured image includes the chuck pin 26. In the captured images of FIGS. 13 and 14, the chuck pin 26 is located at the holding position and is in contact with the peripheral edge of the substrate W. When the chuck pin 26 is not located at the holding position due to the abnormality, the substrate holder 20 cannot appropriately hold the substrate W.

In the captured images of FIGS. 13 and 14, a pin determination region R31 is also illustrated. The pin determination region R31 is set to a region including at least a part of the chuck pin 26 normally located at the holding position. Although only one pin determination region R31 is illustrated in FIG. 13, the pin determination region R31 is actually set corresponding to each of all the chuck pins 26.

At this point, a reference image M31 is previously set. The reference image M31 is an image of the same region as the pin determination region R31, and is generated based on the normal captured image captured by the camera 70 when the chuck pin 26 normally stops at the holding position. The reference image M31 is previously stored in the storage 94.

When the similarity ratio between the pin determination region R31 of the captured image and the reference image M31 is high, it is considered that the chuck pin 26 is normally located at the holding position. Accordingly, the monitoring processing part 92 calculates the similarity ratio between the pin determination region R31 and the reference image M31, and compares the similarity ratio with the pin threshold. The monitoring processing part 92 determines that the chuck pin 26 is located at the holding position when the similarity ratio is equal to or greater than the pin threshold, and determines that the abnormality is generated in the chuck pin 26 when the similarity ratio is less than the pin threshold.

When the processing unit 1 does not supply the processing liquid to the substrate W, the processing liquid does not collide with the chuck pin 26. In the example of FIG. 13, the processing liquid is not contained in the pin determination region R31.

On the other hand, when the processing unit 1 supplies the processing liquid to the substrate W, the processing liquid may collide with the chuck pin 26. Specifically, the processing liquid flows radially outward on the upper surface of the substrate W, and a part of the processing liquid collides with the chuck pin 26. In the example of FIG. 14, the processing liquid is contained in the pin determination region R31. In this case, the similarity ratio decreases even when the chuck pin 26 is normally located at the holding position.

Accordingly, similarly to the outer guard 43, the monitoring processing part 92 may set the pin threshold according to the existence or non-existence of the processing liquid in the pin determination region R31. More specifically, the monitoring processing part 92 sets a larger first pin threshold (corresponding to the first threshold) as the pin threshold when the processing liquid does not exist, and the monitoring processing part 92 sets a second pin threshold (corresponding to the second threshold) smaller than the first pin threshold as the pin threshold when the processing liquid exists.

### <Existence or Non-Existence of Fumes>

The case where fumes derived from the processing liquid are generated will be described below. For example, sometimes the first nozzle 30 discharges a mixed liquid (SPM liquid) of sulfuric acid and hydrogen peroxide water as the processing liquid. For example, the temperature of the SPM liquid is 150° C. to 200° C. For example, the SPM liquid can remove a resist formed on the upper surface of the substrate W. When the resist is sufficiently removed, the processing unit 1 stops the supply of the sulfuric acid. The hydrogen peroxide water is supplied even after the supply of the sulfuric acid is stopped, the hydrogen peroxide water pushes out and discharges the sulfuric acid in the first nozzle 30. Consequently, in the following steps, it is possible to reduce a possibility that the sulfuric acid unintentionally falls from the first nozzle 30.

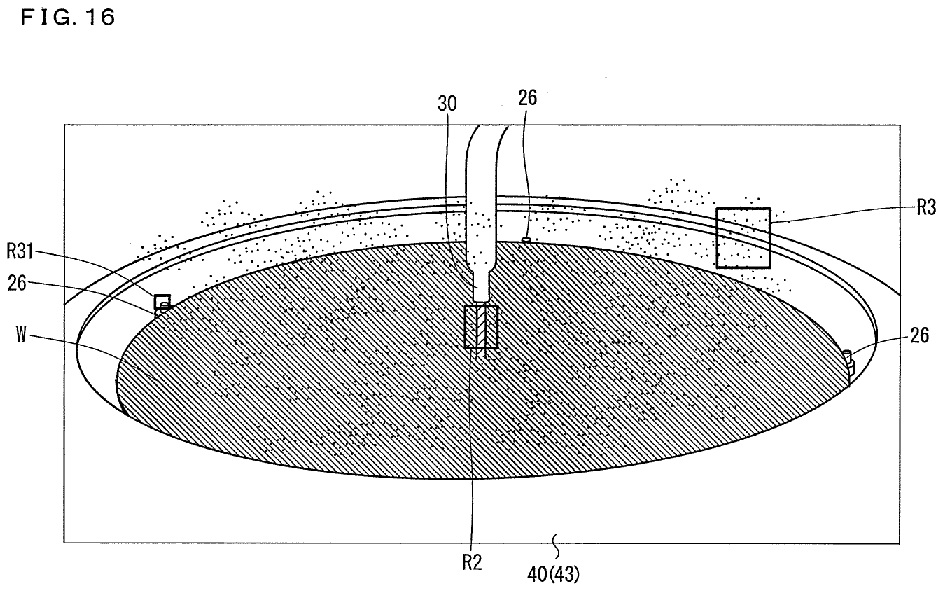

When the hydrogen peroxide water is supplied after the supply of the sulfuric acid is stopped, proportion of the hydrogen peroxide water increases on the upper surface of the substrate W. Accordingly, sometimes a large amount of hydrogen peroxide water reacts with the sulfuric acid to generate an atmosphere including a large number of fine particles called the fumes. FIG. 16 is a view schematically illustrating an example of the captured image when the fumes are generated. In the example of FIG. 16, the fumes are included around the first nozzle 30 in the captured image.

As described above, in the space above the substrate W in the chamber 10, sometimes the fumes are not generated or are generated. That is, the environmental state includes a fume existence state (corresponding to the first environmental state) in which the fumes are generated and a fume non-existence state (corresponding to the second environmental state) in which the fumes are not generated.

When the fumes are generated, the contrast in the captured image decreases as can be understood from FIG. 16. When the contrast decreases, the monitoring accuracy for various monitoring targets may decrease.

Accordingly, in the processing of monitoring the monitoring target, the monitoring processing part 92 varies the determination algorithm according to the fume existence state and the fume non-existence state.

An example of the monitoring processing is similar to the flowchart of FIG. 8. That is, in step S11, the environmental state specifying part 91 determines whether the environmental state is in the fume existence state or the fume non-existence state. As a specific example, the environmental state specifying part 91 may specify the environmental state based on the captured image captured by the camera 70. In this case, step S11 is executed after step S12 (imaging step).

For example, the environmental state specifying part 91 calculates the contrast of the captured image and determines whether the contrast falls within a predetermined fume range. The environmental state specifying part 91 determines that the fumes are generated when the contrast falls within the predetermined fume range, and the environmental state specifying part 91 determines that the fumes are not generated when the contrast is located outside the predetermined fume range. For example, the fume range is previously set by the simulation or experiment.

The environmental state specifying part 91 may calculate the contrast of only a partial region where the fumes are easy to be generated in the captured image. Alternatively, the reference image may be previously stored in the storage 94 when the fumes are not generated, and the environmental state specifying part 91 may specify the environmental state by comparing the captured image with the reference image.

In step S12, the camera 70 captures the image of the imaging region to generate the captured image, and outputs the captured image to the controller 9. In this case, in the liquid processing step (step S3), the camera 70 may continue to capture the image of the imaging region. Consequently, the monitoring target can be monitored over the entire period of the liquid processing step.

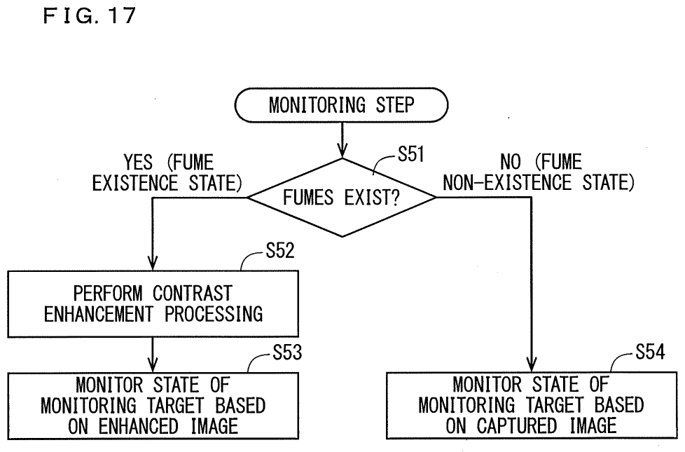

Subsequently, in step S13, the monitoring processing part 92 monitors the state of the monitoring target based on the captured image in the determination procedure according to the environmental state specified by the environmental state specifying part 91. FIG. 17 is a flowchart illustrating a specific example of the monitoring step.

First, the monitoring processing part 92 determines whether the fumes are generated (step S51). The monitoring processing part 92 can recognize the existence or non-existence of the fumes based on the environmental state specified by the environmental state specifying part 91.

When the fumes are generated, namely, when the environmental state is in the fume existence state, the monitoring processing part 92 performs contrast enhancement processing of increasing the contrast on the captured image to generate enhanced image data (hereinafter, simply referred to as an enhanced image) (step S52). For example, the contrast enhancement processing includes known processing such as a histogram equalization method. In the enhanced image, for example, various objects such as the first nozzle 30, the processing liquid discharged from the first nozzle 30, the guard part 40, and the chuck pin 26 are visually recognized more clearly.

Subsequently, the monitoring processing part 92 monitors the state of the monitoring target based on the enhanced image (step S53). For example, the monitoring processing part 92 may monitor the discharge state of the first nozzle 30 based on the discharge determination region R2 of the enhanced image, monitor the height position of the outer guard 43 based on the guard determination region R3 of the enhanced image, or monitor the position of the chuck pin 26 based on the pin determination region R31 of the enhanced image.

On the other hand, when the fumes are not generated, namely, when the environmental state is in the fume non-existence state, the monitoring processing part 92 monitors the state of the monitoring target based on the captured image without performing the contrast enhancement processing on the captured image (step S54). For example, the monitoring processing part 92 may monitor the discharge state of the first nozzle 30 based on the discharge determination region R2 of the captured image, monitor the height position of the outer guard 43 based on the guard determination region R3 of the captured image, or monitor the position of the chuck pin 26 based on the pin determination region R31 of the captured image.

As described above, when the fumes are generated, the monitoring processing part 92 monitors the monitoring target based on a contrast enhancement image. For this reason, the monitoring processing part 92 can monitor the state of the monitoring target with higher accuracy. On the other hand, when the fumes are not generated, the monitoring processing part 92 monitors the state of the monitoring target based on the captured image. For this reason, the monitoring processing part 92 does not need to perform the contrast enhancement processing, and the load on the controller 9 can be reduced.

In the above example, the monitoring processing part 92 changes the existence or non-existence of execution of the contrast enhancement processing according to the existence or non-existence of the fumes, but the present embodiment is not necessarily limited thereto. For example, the monitoring processing part 92 may set the threshold to the larger first threshold in the fume existence state, and set the threshold to the smaller second threshold in the fume non-existence state. Alternatively, the first reference image including the fumes and the normal monitoring target and the second reference image not including the fumes and including the normal monitoring target may be stored in the storage 94. The monitoring processing part 92 may monitor the state of the monitoring target by comparing the captured image with the first reference image in the fume existence state, and monitor the state of the monitoring target by comparing the captured image with the second reference image in the fume non-existence state.

### Second Embodiment

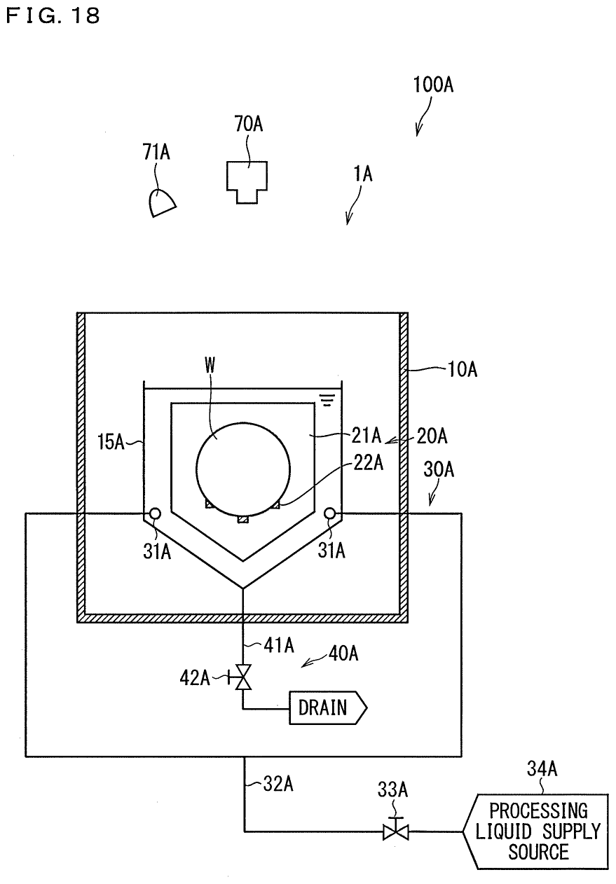

FIG. 18 is a view schematically illustrating an example of a configuration of a substrate processing apparatus 100A according to a second embodiment. The substrate processing apparatus 100A includes a processing unit 1A. Although not illustrated, the substrate processing apparatus 100A includes various configurations such as the load port carrying in and out the carrier accommodating the plurality of substrates W and the substrate conveyance part (not illustrated) conveying the plurality of substrates W between the load port and the processing unit 1A. The substrate processing apparatus 100A may include a plurality of processing units 1A.

The processing unit 1A includes a processing tank 15A, a lifter 20A, a liquid supply part 30A, a liquid drainage part 40A, and a camera 70A.

In the example of FIG. 18, a chamber 10A is also provided. In the example of FIG. 18, the chamber 10A has a box shape that is open vertically upward. An openable and closable lid may be provided at the upper end of the chamber 10A.

The processing tank 15A is provided in the chamber 10A and has a box shape that is open vertically upward. The processing tank 15A stores the processing liquid.

The liquid supply part 30A supplies the processing liquid to the processing tank 15A. In the example of FIG. 18, the liquid supply part 30A includes a nozzle 31A, a liquid supply pipe 32A, and a valve 33A. The nozzle 31A is provided on the lower side in the processing tank 15A. The downstream end of the liquid supply pipe 32A is connected to the nozzle 31A, and the upstream end of the liquid supply pipe 32A is connected to a processing liquid supply source 34A. The processing liquid supply source 34A includes a tank (not illustrated) that stores the processing liquid.

The valve 33A is provided in the liquid supply pipe 32A. When the valve 33A is open, the processing liquid is supplied from the processing liquid supply source 34A to the nozzle 31A through the liquid supply pipe 32A, and discharged from the discharge port of the nozzle 31A to the processing tank 15A. When the valve 33A is closed, the supply of the processing liquid to the processing tank 15A is terminated.

The lifter 20A (corresponding to the substrate holder) holds the substrate W and ascends and descends the held substrate W. The lifter 20A can hold the plurality of substrates W. For example, the lifter 20A holds the plurality of substrates W while the plurality of substrates W are arranged at intervals in the thickness direction of the substrates W. In the example of FIG. 18, the lifter 20A includes a connecting plate 21A and a plurality of support members 22A. The connecting plate 21A is provided in a posture in which the thickness direction of the connecting plate 21A is along the horizontal direction.

The plurality of support members 22A have an elongated shape extending along the thickness direction of the connecting plate 21A, and one end of the support member 22A is connected to the connecting plate 21A. A plurality of grooves (not illustrated) into which the plurality of substrates W are inserted are formed in each support member 22A. When the substrate W is inserted into the groove of the support member 22A, the support member 22A supports the substrate W in a standing posture.

The lifter 20A includes an ascending and descending mechanism (not illustrated), and ascends and descends the plurality of substrates W between the processing position inside the processing tank 15A and a pull-up position vertically above the processing tank 15A. For example, the ascending and descending mechanism includes a ball screw mechanism and a motor, and ascends and descends the connecting plate 21A. Consequently, the plurality of substrates W supported by the support member 22A also ascend and descend. When the lifter 20A descends the plurality of substrates W to the processing position, the plurality of substrates W can be immersed in the processing liquid.

The liquid drainage part 40A drains the processing liquid from the processing tank 15A to the outside. The liquid drainage part 40A includes a liquid drainage pipe 41A and a valve 42A. For example, the upstream end of the liquid drainage pipe 41A is connected to the bottom part of the processing tank 15A, and the downstream end of the liquid drainage pipe 41A is connected to the outside. The valve 42A is provided in the liquid drainage pipe 41A. When the valve 42A is open, the processing liquid is supplied from the processing tank 15A to the outside through the liquid drainage pipe 41A. When the valve 42A is closed, the discharge of the processing liquid is terminated.

When the liquid supply part 30A supplies the processing liquid to the processing tank 15A, the processing liquid is stored in the processing tank 15A, and when the liquid drainage part 40A drains the processing liquid from the processing tank 15A, the processing tank 15A becomes empty. The term “empty” as used herein refers to a state in which at least a part of the bottom part of the processing tank 15A is exposed without being covered with the processing liquid.

As described above, the environmental state in the chamber 10A includes the storage state in which the processing liquid is stored in the processing tank 15A and the empty state in which the processing tank 15A is empty.

The camera 70A is provided vertically above the processing tank 15A, and captures the image of the imaging region including the inside (specifically, the bottom part) of the processing tank 15A. In the example of FIG. 18, the camera 70A is provided above the chamber 10A. In the example of FIG. 18, the camera 70A is provided directly above the processing tank 15A, and the camera 70A is provided such that the imaging direction of the camera 70A is along the vertically downward direction.

In the example of FIG. 18, an illumination part 71A is also provided. The illumination part 71A is also provided vertically above the processing tank 15A. The Illumination part 71A illuminates the imaging region of the camera 70A.

Also in such the processing unit 1A, the controller 9 can monitor various configurations in the chamber 10A as monitoring targets based on the captured image from the camera 70A. As a specific example, the monitoring target includes the bottom part of the processing tank 15A. A fragment of the substrate W may remain at the bottom part of the processing tank 15A. That is, when a chip (that is, cracking) is generated in the plurality of substrates W held by the lifter 20A, the fragment falls to the bottom part of the processing tank 15A.

In this case, after the lifter 20A pulls up the substrate W from the processing tank 15A and passes the substrate W to the substrate conveyance part (not illustrated), the camera 70A captures the image of the imaging region. The controller 9 determines the existence or non-existence of the fragment of the substrate W at the bottom part of the processing tank 15A based on the captured image.

Incidentally, in the storage state in which the processing liquid is stored in the processing tank 15A, it is difficult to visually recognize the bottom part of the processing tank 15A. This is because light is reflected by a liquid level of the processing liquid stored in the processing tank 15A. For this reason, the fragment of the substrates W remaining at the bottom part of the processing tank 15A is also hardly visually recognized. On the other hand, in the empty state where the processing liquid is not stored in the processing tank 15A, the bottom part of the processing tank 15A is easily visually recognized.

Accordingly, in the processing of monitoring the bottom part of the processing tank 15A, the monitoring processing part 92 sets the threshold to a different value according to the storage state and the empty state.

An example of the processing of monitoring the bottom part of the processing tank 15A is similar to the flowchart of FIG. 8. That is, in step S11, the environmental state specifying part 91 determines whether the environmental state is the storage state or the empty state. As a specific example, the environmental state specifying part 91 may specify the environmental state based on the data from the processing controller 93. For example, the processing controller 93 may provide the data indicating the storage state to the environmental state specifying part 91 when the liquid supply part 30A is caused to supply the processing liquid, and the processing controller 93 may output the data indicating the empty state to the environmental state specifying part 91 when the liquid drainage part 40A is caused to discharge the processing liquid to empty the processing tank 15A.

Alternatively, a sensor detecting the existence or non-existence of the processing liquid in the processing tank 15A may be provided in the chamber 10A. The environmental state specifying part 91 may determine the environmental state based on the detection result of the sensor.

Alternatively, the environmental state specifying part 91 may specify the environmental state based on the captured image captured by the camera 70. In this case, step S11 is executed after step S12. When the processing liquid is stored in the processing tank 15A, the plurality of captured images captured in time series may be different from each other due to fluctuation of the liquid level of the processing liquid. On the other hand, when the processing tank 15A is empty, the plurality of captured images captured in time series ideally coincide with each other. Accordingly, the environmental state specifying part 91 may calculate an inter-frame difference between the captured images captured in time series and specify the environmental state based on the inter-frame difference. For example, when the sum of the differences between the frames is equal to or greater than a predetermined liquid threshold, the environmental state specifying part 91 determines that the processing liquid is stored in the processing tank 15A. In other words, the environmental state specifying part 91 determines that the environmental state is in the storage state. On the other hand, when the sum is less than the liquid threshold, the environmental state specifying part 91 determines that the processing liquid is not stored in the processing tank 15A. In other words, the environmental state specifying part 91 determines that the environmental state is in the empty state. For example, the liquid threshold is previously set by the simulation or experiment.

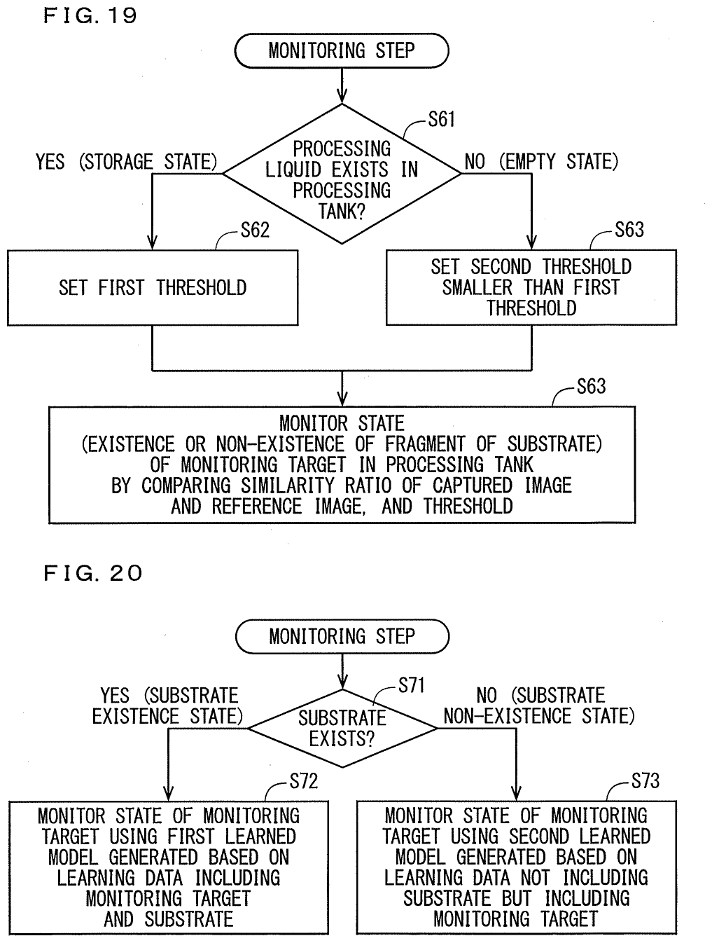

In step S12, the camera 70A captures the image of the imaging region to generate the captured image, and outputs the captured image to the controller 9. In this case, the camera 70A captures the image of the imaging region including the bottom part of the processing tank 15A while the lifter 20A does not hold the plurality of substrates W. Subsequently, in step S13, the monitoring processing part 92 determines the existence or non-existence of the fragment of the substrate W inside the processing tank 15A based on the captured image in the determination procedure according to the environmental state specified by the environmental state specifying part 91. FIG. 19 is a flowchart illustrating a specific example of the monitoring step according to the second embodiment.

First, the monitoring processing part 92 determines whether the processing liquid is stored in the processing tank 15A (step S61). The monitoring processing part 92 can recognize the existence or non-existence of the processing liquid based on the environmental state specified by the environmental state specifying part 91.

When the processing liquid does not exist, namely, when the environmental state is in the empty state, the monitoring processing part 92 sets a first fragment threshold as a fragment threshold used for monitoring the existence or non-existence of the fragment of the substrate W to be described later (step S42). The first fragment threshold is a relatively large value, and for example, is previously set.

Subsequently, the monitoring processing part 92 calculates the similarity ratio between the captured image and a fragment-monitoring reference image. The fragment-monitoring reference image here is the image including the bottom part of the processing tank 15A in which the processing tank 15A is empty and the fragment of the substrate W does not exist. For example, the reference image is generated based on the normal captured image captured by the camera 70 while the processing tank 15A is empty and the fragment of the substrate W does not remain inside the processing tank 15A.

The monitoring processing part 92 determines the existence or non-existence of the fragment of the substrate W by comparing the similarity ratio with the fragment threshold (in this case, the first fragment threshold) (step S63). When the similarity ratio between the captured image and the fragment-monitoring reference image is high, it is considered that the fragment of the substrate W do not remain.

The monitoring processing part 92 determines that the fragment does not remain when the similarity ratio is equal to or greater than the fragment threshold, and the monitoring processing part 92 determines that the fragment remains when the similarity ratio is less than the fragment threshold.

On the other hand, when the processing liquid exists, namely, when the environmental state is in the storage state, the monitoring processing part 92 sets the second fragment threshold as the fragment threshold (step S62). The second fragment threshold is smaller than the first fragment threshold, and for example, is previously set.

Subsequently, the monitoring processing part 92 determines the existence or non-existence of the fragment of the substrate W by comparing the similarity ratio between the captured image and the fragment-monitoring reference image with the fragment threshold (in this case, the second fragment threshold) (step S63). The monitoring processing part 92 determines that the fragment does not remain when the similarity ratio is equal to or greater than the fragment threshold, and the monitoring processing part 92 determines that the fragment is generated when the similarity ratio is less than the fragment threshold.

As described above, when the processing liquid is not stored in the processing tank 15A, the larger first fragment threshold is adopted as the fragment threshold. For this reason, the monitoring processing part 92 can detect the fragment (abnormality) with higher accuracy. That is, when the processing liquid that is a factor decreasing the similarity ratio is not stored, the existence or non-existence of the fragment is determined more strictly using the larger first fragment threshold as the fragment threshold. Consequently, a minute fragment can also be detected.

On the other hand, when the processing liquid is not stored in the processing tank 15A, the second fragment threshold lower than the first fragment threshold is adopted as the fragment threshold. For this reason, the erroneous detection of the fragment due to liquid level reflection of the processing liquid can be reduced.

### Third Embodiment

In a third embodiment, the monitoring processing part 92 uses a first learned model corresponding to the first environmental state and a second learned model corresponding to the second environmental state according to the environmental state. The first learned model is a learned model generated using the machine learning algorithm such as the deep learning, and is generated based on first learning data imaged in the first environmental state. The first learning data imaged in the substrate existence state (first environmental state) is used when the position of the first nozzle 30 is monitored. Specifically, the first learned model is generated by learning with the learning model using teacher data including both a plurality of first learning data imaged when the first nozzle 30 is normally located at the nozzle processing position in the substrate existence state and a label (normal) of the plurality of first learning data and teacher data including both a plurality of first learning data imaged when the first nozzle 30 is not located at the nozzle processing position in the substrate existence state and a label (abnormal) of the plurality of first learning data. The first learned model classifies the captured image into one of a normal category indicating normal and an abnormal category indicating abnormal.

The second learned model is a learned model generated using the machine learning algorithm such as the deep learning, and is generated based on learning data imaged in the second environmental state. The second learning data captured in the substrate non-existence state (second environmental state) is used when the position of the first nozzle 30 is monitored. Specifically, the second learned model is generated by learning with the learning model using the teacher data including both the plurality of second learning data imaged when the first nozzle 30 is normally located at the nozzle processing position in the substrate non-existence state and the label (normal) of the plurality of second learning data and the teacher data including both the plurality of second learning data imaged when the first nozzle 30 is not located at the nozzle processing position in the substrate non-existence state and the label (abnormal) of the plurality of second learning data. The second learned model classifies the captured image into one of the normal category and the abnormal category.

The flowchart of the monitoring processing in the third embodiment is similar to that in FIG. 8. However, the monitoring processing part 92 varies the learned model according to the environmental state. FIG. 20 is a flowchart illustrating an example of the monitoring step according to the third embodiment.

First, the monitoring processing part 92 determines the existence or non-existence of the substrate W in the captured image (step S71). The monitoring processing part 92 can recognize the existence or non-existence of the substrate W based on the environmental state specified by the environmental state specifying part 91.

When the substrate W exists, namely, when the environmental state is in the substrate existence state, the monitoring processing part 92 monitors the position of the first nozzle 30 using the first learned model (step S72). More specifically, the monitoring processing part 92 inputs the captured image to the first learned model, and the first learned model classifies the captured image into either the normal category or the abnormal category.

When the substrate W does not exist, namely, when the environmental state is in the substrate non-existence state, the monitoring processing part 92 monitors the position of the first nozzle 30 using the second learned model (step S73). More specifically, the monitoring processing part 92 inputs the captured image to the second learned model, and the second learned model classifies the captured image into either the normal category or the abnormal category.

As described above, according to the third embodiment, the first learned model generated based on the learning data including the substrate W is used in the substrate existence state. In the substrate existence state, since the captured image includes the substrate W, the first learned model learned based on the first learning data including the substrate W can classify the captured image with high accuracy. In other words, the monitoring processing part 92 can monitor the position of the first nozzle 30 with higher accuracy.

The second learned model generated based on the learning data not including the substrate W is used in the substrate non-existence state. The captured image does not include the substrate W in the substrate non-existence state, so that the second learned model generated based on the second learning data that does not include the substrate W can classify the captured image with high accuracy. In other words, the monitoring processing part 92 can monitor the position of the first nozzle 30 with higher accuracy.

In the above-described example, the existence or non-existence of the substrate W has been described, but the present embodiment is not necessarily limited thereto. For example, as described in the first or second embodiment, the first learned model and the second learned model according to the existence or non-existence of the processing liquid may be prepared, and used according to the environmental state. In short, in the imaging region, the first learned model generated based on the first learning data including the object around the monitoring target and the second learned model generated based on the second learning data not including the object around the monitoring target may be prepared, and used according to the environmental state (the object existence state and the object non-existence state).

### Other Examples

### <Reference Image>

In the above description, in the specific example of the monitoring processing using the reference image according to the environmental state, the substrate existence state (corresponding to the object existence state) and the substrate non-existence state (corresponding to the object non-existence state) are adopted as examples of the first environmental state and the second environmental state, respectively (see also FIGS. 6 and 7). However, the present embodiment is not necessarily limited thereto.

For example, the liquid existence state (corresponding to the object existence state) and the liquid non-existence state (corresponding to the object non-existence state) described above may be adopted as the first environmental state and the second environmental state. That is, the object in the object existence state and the object non-existence state may be the processing liquid. For example, the guard part 40, the chuck pin 26, or the processing tank 15A can be adopted as the monitoring target in this case. When the guard part 40 is the monitoring target, the first reference image in which the guard part 40 is stopped at the normal position in the liquid existence state and the second reference image in which the guard part 40 is stopped at the normal position in the liquid non-existence state are previously set, and one of the first reference image and the second reference image may be used according to the environmental state. The same applies to the monitoring processing when the chuck pin 26 is the monitoring target. When the processing tank 15A is the monitoring target, the first reference image in which the processing tank 15A is normal in the liquid existence state in which the processing liquid is stored and the second reference image in which the processing tank 15A is normal in the liquid non-existence state in which the processing liquid is not stored is previously set, and one of the first reference image and the second reference image may be used according to the environmental state.

The fume existence state (corresponding to the object existence state) and the fume non-existence state (corresponding to the object non-existence state) described above may be adopted as the first environmental state and the second environmental state. That is, the object in the object existence state and the object non-existence state may be fumes derived from the processing liquid generated above the substrate W. For example, the guard part 40 or the chuck pin 26 can be adopted as the monitoring target in this case. In the case where the guard part 40 is the monitoring target, the first reference image in which the guard part 40 is located at the normal position in the fume existence state and the second reference image in which the guard part 40 is located at the normal position in the fume non-existence state are previously set, and one of the first reference image and the second reference image may be used according to the environmental state. The same applies to the monitoring processing when the chuck pin 26 is the monitoring target.

### <Threshold>

In the above example, in the monitoring processing using the threshold according to the environmental state, the liquid existence state (corresponding to the object existence state) and the liquid non-existence state (corresponding to the object non-existence state) are adopted as examples of the first environmental state and the second environmental state, respectively (see also FIGS. 13 and 14). However, the present embodiment is not necessarily limited thereto.

For example, the substrate existence state (corresponding to the object existence state) and the substrate non-existence state (corresponding to the object non-existence state) described above may be adopted as the first environmental state and the second environmental state. That is, the object in the object existence state and the object anon-existence state may be the substrate W in the substrate holder 20. For example, the first nozzle 30 can be adopted as the monitoring target in this case. Specifically, the reference image including the first nozzle 30 in the substrate existence state is previously set, and the position of the first nozzle 30 is calculated by template matching. In the case that the environmental state is in the substrate existence state, it may be determined that the abnormality related to the first nozzle 30 is generated when the difference between the calculated position of the first nozzle 30 and the target position is equal to or larger than the higher first threshold. In the case where the environmental state is in the substrate non-existence state, it may be determined that the abnormality is generated when the difference is equal to or larger than the lower second threshold.

The patterned substrate state (corresponding to the object existence state) and the uniform substrate state (corresponding to the object non-existence state) described above may be adopted as the first environmental state and the second environmental state. That is, the object in the object existence state and the object non-existence state may be the pattern in the substrate W. For example, the first nozzle 30 can be adopted as the monitoring target in this case. Specifically, the reference image including the first nozzle 30 in the uniform substrate state is previously set, and the position of the first nozzle 30 is calculated by template matching. In the case where the environmental state is in the uniform substrate state, it may be determined that the abnormality is generated when the calculated difference between the position of the first nozzle 30 and the target position is greater than or equal to the higher first threshold. In the case where the environmental state is the patterned substrate state, it may be determined that the abnormality is generated when the difference is greater than or equal to the lower second threshold.

The fume plate state (corresponding to the object existence state) and the fume non-existence state (corresponding to the object non-existence state) described above may be adopted as the first environmental state and the second environmental state. That is, the object in the object existence state and the object non-existence state may be the fumes. For example, the first nozzle 30 or the guard part 40 can be adopted as the monitoring target in this case. The same step as described above is performed when the monitoring target is the first nozzle 30. When the guard part 40 is in the monitoring target, the reference image including the guard part 40 normally positioned in the fume non-existence state may be previously set. In the case where the environmental state is the fume non-existence state, it may be determined that the abnormality related to the guard part 40 is generated when the similarity ratio between the captured image and the reference image is less than the higher first threshold. In the case where the environmental state is the fume existence state, it may be determined that the abnormality is generated when the similarity ratio is less than the lower second threshold.

In addition, the liquid existence state (corresponding to the object existence state) and the liquid non-existence state (corresponding to the object non-existence state) described above may be adopted as the first environmental state and the second environmental state. For example, the processing tank 15A may be adopted as the monitoring target in this case. In this case, in the case where the environmental state is in the liquid non-existence state while the reference image including the normal processing tank 15A in the liquid non-existence state is previously set, it may be determined that the abnormality related to the processing tank 15A is generated when the similarity ratio between the captured image and the reference image is less than the higher first threshold, and in the case where the environmental state is in the liquid existence state, it may be determined that the abnormality is generated when the similarity ratio is less than the lower second threshold.

### <Machine Learning>

Also in the monitoring processing using the learned model according to the environmental state, the first environmental state and the second environmental state are not limited to the above example. For example, the fume existence state (corresponding to the object existence state) and the fume non-existence state (corresponding to the object non-existence state) described above may be adopted as the first environmental state and the second environmental state. In this case, for example, the guard part 40 may be adopted as the monitoring target. In this case, the learned model generated based on a plurality of teacher data in the case of the fume non-existence state and the learned model generated based on a plurality of teacher data in the case of the fume existence state are used. When the environmental state is the fume existence state, the captured image may be input to the learned model according to the fume existence state to determine the existence or non-existence of the abnormality related to the guard part 40. When the environmental state is the fume non-existence state, the captured image may be input to the learned model according to the fume non-existence state to determine the existence or non-existence of the abnormality related to the guard part 40.

In addition, the liquid existence state (corresponding to the object existence state) and the liquid non-existence state (corresponding to the object non-existence state) described above may be adopted as the first environmental state and the second environmental state. In this case, for example, the guard part 40, the chuck pin 26, or the processing tank 15A may be adopted as the monitoring target. Specifically, the learned model generated based on the plurality of teacher data in the case of the processing liquid non-existence state and the learned model generated based on the plurality of teacher data in the case of the processing liquid existence state are used. When the environmental state is the liquid existence state, the captured image may be input to the learned model according to the liquid existence state to determine the existence or non-existence of the abnormality related to the guard part 40, the chuck pin 26, or the processing tank 15A. When the environmental state is the liquid non-existence state, the captured image may be input to the learned model according to the liquid non-existence state to determine the existence or non-existence of the abnormality.

As described above, the substrate processing apparatus 100 and the monitoring method have been described in detail, but the above description is an example in all aspects, and these are not limited thereto. Innumerable modifications not illustrated can be envisaged without departing from the scope of the present disclosure. The configurations described in the above embodiments and the modifications can appropriately be combined as long as they are not inconsistent with each other.

### EXPLANATION OF REFERENCE SIGNS

10, 10A: chamber
100: substrate processing apparatus
20: substrate holder
20A: substrate holder (lifter)
26: chuck pin
30: nozzle (first nozzle)
60: nozzle (second nozzle)
68: nozzle (third nozzle)
41: guard (inner guard)
42: guard (middle guard)
43: guard (outer guard)
70, 70A: camera
9, 9A: camera
94: storage
S11: environmental state specifying step (step)
S12: imaging step (step)
S13: monitoring step (step)
W: substrate

1. A substrate processing apparatus comprising:
a chamber;
a substrate holder that holds a substrate in said chamber;
a camera that captures an image of an imaging region including a monitoring target in said chamber to generate captured image data; and
a controller that specifies an environmental state in said imaging region, monitors a state of said monitoring target based on said captured image data in a first determination procedure corresponding to a first environmental state when said environmental state is in said first environmental state, and monitors said state of said monitoring target based on said captured image data in a second determination procedure corresponding to a second environmental state and different from said first determination procedure when said environmental state is in said second environmental state different from said first environmental state.

2. The substrate processing apparatus according to claim 1, wherein said controller specifies said environmental state based on said captured image data.

3. The substrate processing apparatus according to claim 1, further comprising a storage in which a plurality of reference image data corresponding to said environmental state are recorded,
wherein said controller
monitors said state of said monitoring target based on comparison between said captured image data and first reference image data corresponding to said first environmental state as said first determination procedure when said environmental state is in said first environmental state, and
monitors said state of said monitoring target based on comparison between said captured image data and second reference image data corresponding to said second environmental state as said second determination procedure when said environmental state is in said second environmental state.

4. The substrate processing apparatus according to claim 3, wherein
said first environmental state includes a state in which a predetermined object exists in said imaging region,
said second environmental state includes a state in which said object does not exist in said imaging region,
said first reference image data is an image including said object and said monitoring target, and
said second reference image data is an image not including said object but including said monitoring target.

5. The substrate processing apparatus according to claim 1, wherein an algorithm of said first determination procedure and an algorithm of said second determination procedure are different from each other.

6. The substrate processing apparatus according to claim 1, wherein a threshold for monitoring said state of said monitoring target that is used in said first determination procedure is different from a threshold for monitoring said state of said monitoring target that is used in said second determination procedure.

7. The substrate processing apparatus according to claim 6, further comprising a storage in which reference image data is recorded,
wherein said first environmental state includes a state in which a predetermined object exists in said imaging region,
said second environmental state includes a state in which said object does not exist in said imaging region,
said reference image data is an image that does not include said object and includes the monitoring target, and
said controller
monitors said state of said monitoring target based on comparison between a similarity ratio of said captured image data and said reference image data and a first threshold as said first determination procedure when said environmental state is in said first environmental state and
monitors said state of said monitoring target based on comparison between said similarity ratio of said captured image data and said reference image data and a second threshold smaller than said first threshold as said second determination procedure when said environmental state is in said second environmental state.

8. The substrate processing apparatus according to claim 4, further comprising a nozzle that supplies a processing liquid to said substrate from a nozzle processing position above said substrate held by said substrate holder,
wherein said object includes fumes that are generated above said substrate and derived from said processing liquid.

9. The substrate processing apparatus according to claim 1, wherein
said first environmental state includes a state in which a predetermined object exists in said imaging region,
said second environmental state includes a state in which said object does not exist in said imaging region,
said controller inputs said captured image data to a first learned model as said first determination procedure, and inputs said captured image data to a second learned model as said second determination procedure,
said first learned model is a learned model generated based on a plurality of learning data including said monitoring target and said object, and classifies said captured image data into one of a normal category indicating that said captured image data is normal and an abnormal category indicating that said captured image data is abnormal, and
said second learned model is a learned model generated based on a plurality of learning data not including said object but including said monitoring target, and classifies the captured image data into one of said normal category and said abnormal category.

10. The substrate processing apparatus according to claim 1, wherein said monitoring target includes at least one of a chuck pin of said substrate holder, a nozzle that supplies a processing liquid to said substrate held by said substrate holder, and a cylindrical guard that receives said processing liquid scattered from a peripheral edge of said substrate held by said substrate holder.

11. The substrate processing apparatus according to claim 5, further comprising a nozzle that supplies a processing liquid to said substrate from a nozzle processing position above said substrate held by said substrate holder,
wherein said first environmental state includes a patterned substrate state in which a pattern is formed on an upper surface of said substrate held by said substrate holder,
said second environmental state includes a uniform substrate state in which a pattern is not formed on the upper surface of said substrate held by said substrate holder, and
said controller
calculates an index indicating a variation in a pixel value in a discharge determination region located immediately below said nozzle in said captured image data and determines existence or non-existence of a droplet of said processing liquid dropped from said nozzle based on comparison between said index and a threshold as said first determination procedure when said environmental state is in said uniform substrate state, and
inputs said captured image data to a learned model to determine the existence or non-existence of said droplet as said second determination procedure when said environmental state is in said patterned substrate state.

12. The substrate processing apparatus according to claim 5, further comprising a nozzle that supplies a processing liquid to said substrate held by said substrate holder,
wherein said first environmental state includes a fume existence state in which fumes derived from said processing liquid are generated above said substrate held by said substrate holder,
said second environmental state includes a fume non-existence state in which said fumes are not generated, and
the controller
generates enhanced image data by performing contrast enhancement processing on said captured image data as said first determination procedure and monitors said state of said monitoring target based on said enhanced image data when said environmental state is in said fume existence state, and
monitors said state of said monitoring target based on said captured image data without performing said contrast enhancement processing as said second determination procedure when said environmental state is in said fume non-existence state.

13. A monitoring method comprising:
an environmental state specifying step of specifying an environmental state in an imaging region including a monitoring target in a chamber accommodating a substrate holder holding a substrate;
an imaging step of capturing an image of said imaging region by a camera to generate captured image data; and
a monitoring step of monitoring a state of said monitoring target based on said captured image data in a first determination procedure corresponding to said first environmental state when said environmental state is in said first environmental state, and monitoring said state of said monitoring target based on said captured image data in a second determination procedure corresponding to said second environmental state and different from said first determination procedure when said environmental state is in a second environmental state different from said first environmental state.
